(19) United States
(12) Patent Application Publication
(10) Pub. No.: US 2011/0126891 A1
(43) Pub. Date: Jun. 2, 2011

(54) Solar Cell Element, Color Sensor and Method of Manufacturing Light Emitting Element and Light Receiving Element

(76) Inventors: Hajime Goto, Saitama (JP); Hirotaka Endo, Saitama (JP); Kenji Hiruma, Hokkaido (JP); Junichi Motohisa, Hokkaido (JP); Takashi Fukui, Hokkaido (JP)

(21) Appl. No.: 12/955,193

(22) Filed: Nov. 29, 2010

(30) Foreign Application Priority Data
Nov. 30, 2009 (JP) JP2009-272140
Nov. 24, 2010 (JP) JP2010-261564

(51) Int. Cl. H01L 31/06; H01L 31/18; H01L 31/0352

(52) U.S. Cl. 136/255; 438/94; 257/21; 438/24; 257/E31.054; 257/E31.033

(57) ABSTRACT

A solar cell element having improved power generation efficiency is provided. A solar cell element 100 has a substrate 110, a mask pattern 120, semiconductor nanorods 130, a first electrode 150 and a second electrode 160. The semiconductor nanorods 130 are disposed in triangular lattice form as viewed in plan on the substrate 110. The ratio p/d of the center-to-center distance p between each adjacent pair of the semiconductor nanorods 130 and the minimum diameter d of the semiconductor nanorods 130 is within the range from 1 to 7. Each semiconductor nanorod 130 has a central nanorod 131 formed of a semiconductor of a first conduction type, a first cover layer 132 formed of an intrinsic semiconductor and covering the central nanorod 131, and a second cover layer 138 formed of a semiconductor of a second conduction type and covering the first cover layer 132.

This application claims the foreign priority benefit under 35 U.S.C. §119 of Japanese Patent Application No. 2009-272140 filed on Nov. 30, 2009, and Japanese Patent Application No. 2010-261564 filed on Nov. 24, 2010, respectively, the disclosures of which are incorporated herein by reference.

### BACKGROUND OF THE INVENTION

1. Field of the Invention

The present invention relates to a solar cell element and a color sensor each having semiconductor nanorods and to a method of manufacturing a light emitting element and a light receiving element each having semiconductor nanorods.

2. Description of the Related Art

1. Solar Cell Element

Solar cell elements having semiconductor nanorods (nanowires) are capable of increasing the surface area with respect to incident light and are, therefore, thought to be superior to thin-film solar cell elements in power generation efficiency. In recent years, several reports have been made of solar cell elements having semiconductor nanorods (see, for example, Japanese Patent Laid-Open Nos. 2008-182226, 2008-53730 and 2008-28118, E. C. Garnett, et al., “Silicon nanowire radial p-n junction solar cells”, Journal of American Chemical Society, Vol. 130, (2008), pp. 9224-9225. (hereinafter referred to as document 1), B. Tian, et al., “Coaxial silicon nanowires as solar cells and nanoelectric power sources”, Nature, Vol. 449, (2007), pp. 885-889. (hereinafter referred to as document 2), T. J. Kempa, et al., “Single and tandem axial p-i-n nanowire photovoltaic devices”, Nano letters, Vol. 8, (2008), pp. 3456-3460. (hereinafter referred to as document 3), and A. Kandala, et al., “General theoretical considerations on nanowire solar cell designs”, Physica Status Solidi (a), Vol. 206, (2009), pp. 173-178. (hereinafter referred to as document 4).

A solar cell element (photovoltaic device) described in Japanese Patent Laid-Open No. 2008-182226 has a substrate, a multilayer film formed on the substrate and an elongated nanostructure formed on the multilayer film. Each of the multilayer film and the nanostructure includes a p-n junction. Also, the multilayer film and the nanostructure form a tandem junction connected in a tunnel junction manner.

A solar cell element (photovoltaic unit) described in Japanese Patent Laid-Open No. 2008-53730 has a substrate, an elongated nanostructure of a first conduction type formed on the substrate and a conformal layer of a second conduction type covering the nanostructure. The nanostructure of the first conduction type and the conformal layer of the second conduction type form a p-n junction.

Documents 1 and 2 give descriptions of the power generation efficiency of a core-shell-type solar cell having a p-n junction formed in the radial direction of a semiconductor nanorod. Japanese Patent Laid-Open No. 2008-28118 and documents 3 and 4 give descriptions of tandem solar cells formed of semiconductor nanorods.

On the other hand, a number of reports have been made of thin-film tandem solar cell elements well known before (see, for example, R. R. King, et al., “40% efficient metamorphic GaInP/GaInAs/Ge multijunction solar cells”, Applied physics Letters, Vol. 90, (2007), pp. 183516-1-183516-3. (hereinafter referred to as document 5), and K. W. J. Barnham, et al., “A new approach to high-efficiency multi-bandgap solar cells”, Journal of Applied Physics, Vol. 67, (1990), pp. 3490-3493. (hereinafter referred to as document 6). Document 5 gives a description of a thin-film tandem high-efficiency solar cell element. Document 6 gives a description of a thin-film solar cell element using a p-n junction and having a superlattice structure formed in an intrinsic layer (i-layer) formed at the p-n junction interface. The superlattice structure of this solar cell element includes in the i-layer a quantum well layer formed of a semiconductor having an energy bandgap smaller than those of semiconductors respectively forming the p-, i- and n-layers. Thus, the solar cell having the superlattice structure can use light having energy smaller than those of the energy bandgaps of the semiconductors respectively forming the p-, i- and n-layers.

The conventional solar cell elements described in Japanese Patent Laid-Open Nos. 2008-182226, 2008-53730 and 2008-28118 and documents 1 and 2 and having semiconductor nanorods, however, have a problem in that they are incapable of using light having energy smaller than those of the energy bandgaps of the semiconductor forming the p-n junction (or the p-i-n junction). It is, therefore, difficult to desire a further improvement in power generation efficiency of the conventional solar cell elements having semiconductor nanorods.

The conventional solar cell element described in Japanese Patent Laid-Open No. 2008-182226 and having semiconductor nanorods also has a problem in that dislocation due to a difference in lattice constant between crystals occurs at the junction interface between the multilayer film on the substrate and the semiconductor nanorods to cause a reduction in performance of the solar cell element.

Further, the conventional solar cell elements described in Japanese Patent Laid-Open No. 2008-28118 and documents 3 and 4 and having semiconductor nanorods have a problem in that carriers diffused in the surface of the semiconductor nanorods in the carriers generated by irradiation with light are captured by a surface state and, therefore, the generation efficiency is reduced.

In the conventional thin-film solar cell element described in document 6, a plurality of quantum well layers may be disposed at intervals of several nanometers or less in the superlattice structure so that wave functions of electrons or positive holes in each adjacent pair of quantum well layers are superposed on each other. In this way, recombination of carriers (electrons and positive holes) generated in one quantum well layer can be prevented to improve the power generation efficiency. However, if in the conventional structure a plurality of quantum well layers may be disposed at intervals of several nanometers or less, strain in the crystal lattice due to the heterojunction is increased to cause crystal dislocation. This crystal dislocation causes a reduction in performance of the solar cell element. The same problem also occurs in a case where not quantum well layers but buried layers including quantum dots are disposed.

The present invention has been achieved in consideration of these points, and an object of the present invention is to provide a solar cell element having a higher power generation efficiency and a method of manufacturing the solar cell element.

2. Color Sensor

Color sensors are known as a semiconductor light detection element for converting wavelength components corresponding to red light, green light and blue light contained in visible light into electrical signals (see, for example, Japanese Patent Laid-Open No. 2007-27462, National Publication of International Patent Application No. 2001-515275, and M. Topic, et al., “Stacked a-SiC:H/a-Si:H heterostructures for bias-controlled three-color detectors”, Journal of Non-Crystalline Solids, Vol. 198-200, (1996), pp. 1180-1184 (hereinafter referred to as document 7).

Japanese Patent Laid-Open No. 2007-27462 gives a description of a color sensor having a light absorption portion formed of mixed crystal (SiGe) of semiconductor silicon (Si) and germanium (Ge). This color sensor has three light absorption layers formed of the mixed crystal of SiGe on a substrate. The mixture ratio of Si and Ge in the layers is successively changed between the upper, middle and lower layers. Blue light is absorbed in the upper layer; green light in the middle layer; and red light in the lower layer.

National Publication of International Patent Application No. 2001-515275 gives a description of a color sensor having three amorphous silicon (a-Si) layers formed on a substrate made of glass. Between the layers, a transparent contact is formed. Each a-Si layer constitutes a diode. In the a-Si layers, red light, green light and blue light are respectively absorbed to produce photoelectromotive force.

Document 7 gives a description of a color sensor using a-Si.

Reports have also been made of p-n-junction-type light detection elements using semiconductor nanorods (see, for example, National Publication of International Patent Application No. 2004-535066).

National Publication of International Patent Application No. 2004-535066 gives a description of a self-standing semiconductor nanorod having a minimum width of 500 nm or less. According to this description, the semiconductor nanorod may include an n-type semiconductor and a p-type semiconductor and may become an electrical component of a photodetector, a p-n solar cell or the like.

The conventional color sensors described in National Publication of International Patent Application No. 2001-515275, National Publication of International Patent Application No. 2004-535066 and document 7, however, have a problem in that part of incident light is lost by reflection on the flat semiconductor surface and, therefore, incident light cannot be sufficiently utilized.

The present invention has been achieved in consideration of this point, and an object of the present invention is to provide a color sensor having a smaller reflection loss and a method of manufacturing the color sensor.

3. Method of Manufacturing Light Emitting Element and Light Receiving Element

Reports have been made of p-n-junction-type light emitting elements (LEDs) having semiconductor nanorods (see, for example, Japanese Patent Laid-Open No. 2009-049209).

Japanese Patent Laid-Open No. 2009-049209 gives a description of a method of manufacturing a p-n-junction-type light emitting element (LED) by forming on a substrate an insulating film having a plurality of openings and growing semiconductor nanorods having p-n junctions from the openings.

The conventional manufacturing method described in Japanese Patent Laid-Open No. 2009-049209, however, use separate processes for manufacturing a light emitting element and a light receiving element and therefore has a problem in terms of manufacturing cost.

The present invention has been achieved in consideration of this point, and an object of the present invention is to provide a method of manufacturing a light emitting element and a light receiving element with higher efficiency.

### SUMMARY OF THE INVENTION

The inventors made studies about causes of failure to obtain a sufficiently high power generation efficiency in conventional solar cell elements having semiconductor nanorods and knew that the conventional solar cell elements were incapable of sufficiently absorbing incident light in some cases. The inventors further made studies on the basis of this knowledge and attained the present invention by finding that when the semiconductor rods were disposed in a triangular lattice form as viewed in plan on a substrate, a reduction in reflectance to incident light and an improvement in absorption of incident light were achieved by setting the ratio p/d of the center-to-center distance p between each adjacent pair of the semiconductor nanorods to the minimum diameter d of the semiconductor nanorods within a predetermined range.

To achieve the above-described object, the present invention provides a solar cell element having a substrate, a mask pattern disposed on a surface of the substrate and having two or more openings, two or more semiconductor nanorods extending upward from the surface of the substrate through the openings, a first electrode connected to lower ends of the semiconductor nanorods, and a second electrode connected to upper ends of the semiconductor nanorods, wherein the semiconductor nanorods are disposed in triangular lattice form as viewed in plan on the substrate, and the ratio p/d of the center-to-center distance p between each adjacent pair of the semiconductor nanorods to the minimum diameter d of the semiconductor nanorods is within the range from 1 to 7, and wherein each semiconductor nanorod has a central nanorod formed of a semiconductor of a first conduction type, a first cover layer formed of an intrinsic semiconductor and covering the central nanorod, and a second cover layer formed of a semiconductor of a second conduction type and covering the first cover layer.

In the application, “triangular lattice” means a lattice having lattice points corresponding to points of intersection of a plurality of straight lines parallel to the sides of a triangle freely selected.

In the solar cell element of the present invention, the semiconductor nanorods are disposed in triangular lattice form as viewed in plan on the substrate such that the ratio p/d of the center-to-center distance p between each adjacent pair of the semiconductor nanorods to the minimum diameter d of the semiconductor nanorods is within the range from 1 to 7, thereby reducing the reflectance to incident light and increasing the absorption. When p/d is lower than 1 or higher than 7, the reflectance to incident light cannot be sufficiently reduced.

More preferably, p/d is set within the range from 1.5 to 5 to reduce the reflectance to incident light.

Also, in the solar cell element of the present invention, each semiconductor nanorod has a central nanorod formed of a semiconductor of a first conduction type, a first cover layer formed of an intrinsic semiconductor and covering the central nanorod, and a second cover layer formed of a semiconductor of a second conduction type and covering the first cover layer. The first conduction type is the n-type or the p-type. When the first conduction type is the n-type, the second conduction type is the p-type. When the first conduction type is the p-type, the second conduction type is the n-type.

Accordingly, the central nanorod, the first cover layer and the second cover layer can form a p-i-n junction.

Preferably, the solar cell element of the present invention further has a surface protective layer covering the second cover layer and formed of a semiconductor having an energy bandgap larger than those of the semiconductor of the first conduction type, the semiconductor of the second conduction type and the intrinsic semiconductor.

Preferably, in the solar cell element of the present invention, the central nanorod has a first region formed of a first semiconductor and formed on the substrate, a second region formed of a second semiconductor having an energy bandgap larger than that of the first semiconductor and formed on the first region, and a third region formed of a third semiconductor having an energy bandgap larger than that of the second semiconductor and formed on the second region.

In the solar cell element of the present invention, when the central nanorod has the first to third regions, the central nanorod may further has a fourth region formed of a fourth semiconductor having an energy bandgap larger than that of the third semiconductor and formed on the third region.

Preferably, in the solar cell element of the present invention, the first cover layer has a buried layer including a quantum well layer or quantum dots. In such a case, it is preferable that the first cover layer have two or more quantum barrier layers formed of a first intrinsic semiconductor, and a quantum well layer formed of a second intrinsic semiconductor having an energy bandgap smaller than that of the first intrinsic semiconductor, and that the quantum well layer be sandwiched between the quantum barrier layers. In such a case, it is also preferable that the first cover layer have two or more quantum barrier layers formed of a first intrinsic semiconductor, and a buried layer including the first intrinsic semiconductor and quantum dots formed of a second intrinsic semiconductor having an energy bandgap smaller than that of the first intrinsic semiconductor, that the buried layer be sandwiched between the quantum barrier layers, and that the quantum dots be dispersed in the first intrinsic semiconductor in the buried layer.

The present invention also provides a solar cell element having a substrate, a mask pattern disposed on a surface of the substrate and having two or more openings, two or more semiconductor nanorods extending upward from the surface of the substrate through the openings, a first electrode connected to lower ends of the semiconductor nanorods, and a second electrode connected to upper ends of the semiconductor nanorods, wherein each semiconductor nanorod has a central nanorod formed of a semiconductor of a first conduction type, a first cover layer formed of a semiconductor of a second conduction type and covering the central nanorod, a second cover layer formed of a semiconductor of the first conduction type and covering the first cover layer, a third cover layer formed of a semiconductor of the second conduction type and covering the second cover layer, a fourth cover layer formed of semiconductor of the first conduction type and covering the third cover layer, and a fifth cover layer formed of a semiconductor of the second conduction type and covering the fourth cover layer, wherein the semiconductors forming the fourth cover layer and the fifth cover layer have an energy bandgap larger than those of the semiconductors forming the second cover layer and the third cover layer, and wherein the semiconductors forming the second cover layer and the third cover layer have an energy bandgap larger than that of the semiconductor forming the first cover layer.

The solar cell element in which the first cover layer has a buried layer including a quantum well layer or quantum dots can be manufactured by a method of manufacturing the solar cell element including forming a mask pattern having an opening on a surface of a substrate, forming a central nanorod on the surface of the substrate exposed through the opening by causing crystal growth of a semiconductor of a first conduction type, forming a first cover layer around the central nanorod by metal organic chemical vapor deposition, molecular beam epitaxy or chemical vapor deposition, the first cover layer being formed of an intrinsic semiconductor, forming a second cover layer around the first cover layer, the second cover layer being formed of a semiconductor of a second conduction type, and forming a first electrode and second electrode, wherein the first cover layer has a quantum barrier layer formed by supplying a raw material gas of a first composition, and thereafter has a buried layer including a quantum well layer or quantum dots formed by supplying a raw material gas of a second composition.

The present invention also provides a color sensor having a substrate, a mask pattern disposed on a surface of the substrate, the mask pattern being sectioned into three or more regions corresponding to RGB, openings being formed in each of the three or more regions, two or more semiconductor nanorods extending upward from the surface of the semiconductor substrate through the openings and having a p-n junction or a p-i-n junction, a first electrode connected to lower ends of the semiconductor nanorods, a second electrode connected to upper ends of the semiconductor nanorods, wherein the composition of the semiconductor nanorods is changed with respect to the three or more regions.

The present invention further provides a method of simultaneously manufacturing a light emitting element and a light receiving element, including A) preparing a substrate having a surface covered with a mask pattern, the mask pattern being sectioned into a region where the light emitting element is to be formed and a region where the light receiving element is to be formed, two or more openings through which a surface of the substrate is exposed being formed in each of the region where the light emitting element is to be formed and the region where the light receiving element is to be formed, the size of the openings or the center-to-center distance between the openings being changed with respect to the region where the light emitting element is to be formed and the region where the light receiving element is to be formed, and B) growing, through the openings, semiconductor nanorods from the substrate covered with the mask pattern, by forming a layer formed of an n-type semiconductor and forming a layer formed of a p-type semiconductor.

### BRIEF DESCRIPTION OF THE DRAWINGS

FIG. 1 is a plan view showing an array of semiconductor nanorods;

FIG. 2 is a perspective view of the construction of the semiconductor nanorod array in a first embodiment;

FIG. 3 is a graph showing the relationship between the ratio p/d of the center-to-center distance p between semiconductor nanorods and the minimum diameter d of the semiconductor nanorods, and the reflectance of a solar cell element;

FIG. 4 is a perspective view of the construction of the solar cell element in the first embodiment;

FIG. 5 is a diagram showing the construction of a semiconductor nanorod of the solar cell element in the first embodiment;

FIG. 6 is a sectional view of a semiconductor nanorod of a solar cell element in a second embodiment;

FIG. 7 is a sectional view of a semiconductor nanorod of a solar cell element in a third embodiment;

FIG. 8 is a sectional view of a semiconductor nanorod of a solar cell element in a fourth embodiment;

FIG. 9 is a sectional view of a semiconductor nanorod of a solar cell element in a fifth embodiment;

FIG. 10 is a sectional view of a semiconductor nanorod of a solar cell element in a sixth embodiment;

FIG. 11 is a sectional view of a semiconductor nanorod of a solar cell element in a seventh embodiment;

FIG. 12 is a sectional view of a semiconductor nanorod of a solar cell element in an eighth embodiment;

FIG. 13 is a perspective view of the construction of a color sensor in a ninth embodiment;

FIG. 14 is a diagram schematically showing a method of manufacturing the color sensor in the ninth embodiment;

FIG. 15 is a perspective view of another construction of the color sensor in the ninth embodiment;

FIG. 16 is a perspective view for explaining a manufacturing method in a tenth embodiment;

FIG. 17 is a diagram schematically showing an example of use of light emitting and light receiving elements manufactured by the manufacturing method in the tenth embodiment; and

FIG. 18 is a diagram schematically showing an example of use of light emitting and light receiving elements manufactured by the manufacturing method in the tenth embodiment.

### DETAILED DESCRIPTION OF THE PREFERRED EMBODIMENTS

2. Solar Cell Element of the Present Invention

A solar cell element of the present invention has a substrate, a mask pattern, two or more semiconductor nanorods, a first electrode and a second electrode. The solar cell element of the present invention is characterized by including quantum well layers or quantum dots in semiconductor nanorods, as described below.

The substrate is not particularly specified if it is capable of growing semiconductor nanorods. Examples of the material of the substrate include a semiconductor, a glass, a metal, a plastic, and a ceramic. Examples of the semiconductor constituting the substrate include GaAs, InP, Si, InAs, GaN, SiC and Al₂O₃. A semiconductor substrate is preferable, because forming semiconductor nanorods from the surface of the semiconductor substrate is easier to perform.

The mask pattern is a thin film disposed on the substrate surface and having two or more openings. If the substrate is a semiconductor crystal substrate, it is preferable that the mask pattern be disposed on the crystal axis (111) plane of the semiconductor crystal constituting the substrate. By growing a central nanorod in each semiconductor nanorod from the crystal axis (111) plane, the direction of extension of the central nanorod can be aligned with the crystal axis (111) direction of the semiconductor crystal. The material of the mask pattern is not particularly specified if it is capable of inhibiting the growth of the central nanorod in the semiconductor nanorod. Examples of the material of the mask pattern include an inorganic insulating material, a metal, a plastic, a ceramic and a combination of these materials. Examples of the inorganic insulating material include SiO₂ and SiN. Examples of the metal include W, WSi, Ti, Mo, Pt, MoSi, Ni, NiSi, WAl, TiAl and MoAl. The film thickness of the mask pattern is not particularly specified. A mask pattern film thickness of several nanometers or more may suffice. The film thickness of the mask pattern may be equal to the length of the semiconductor nanorod (about several microns).

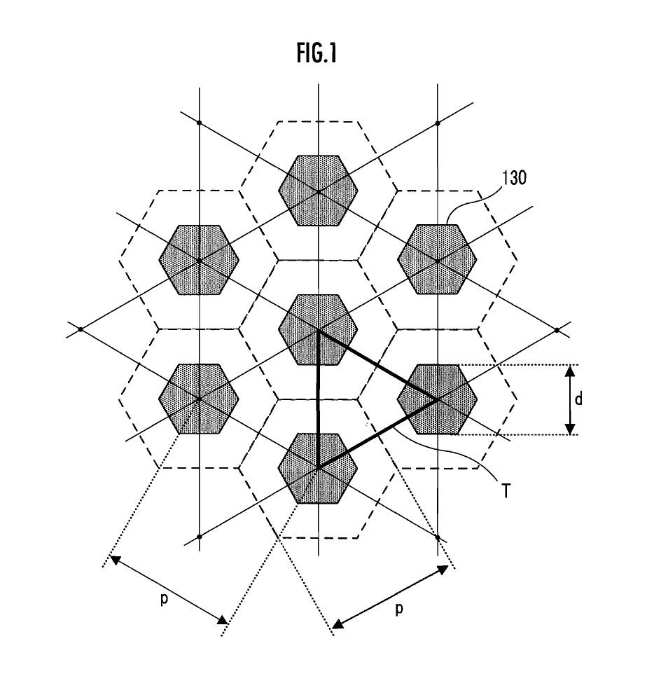

As mentioned above, two or more openings are formed in the mask pattern. The openings are formed therethrough to reach the substrate surface. The substrate surface is exposed in the openings. With the openings, in manufacture of the solar cell element of the present invention, the position at which the central nanorod (described below) in the semiconductor nanorod is grown and the thickness and the shape of the central nanorod are specified. The openings may have any shape, e.g., a circular, triangular, rectangular or a hexagonal shape. From the view point of manufacturing cost involving the manufacturing yield and manufacturing accuracy of the mask pattern, it is preferable that the size (diameter) of the openings be 10 nm or more. If each semiconductor nanorod has a heterojunction having a difference in lattice constant, it is preferable, from the viewpoint of minimizing the generation density of crystal dislocations, that the sectional area and the surface area of the semiconductor nanorod be small. Accordingly, it is preferable that the sectional area of each central nanorod also be small. According to these viewpoints, the size (diameter) of the openings may be within the range from 10 nm to several hundred nm. The center-to-center distance between the openings may be 5 μm or less. It is preferable that the openings be arrayed in triangular lattice form, as described below. “Triangular lattice” means a lattice having lattice points corresponding to points of intersection of a plurality of straight lines parallel to the sides of a triangle freely selected. In other words, the openings are disposed in a hexagonal close-packed array (see FIG. 1)

The semiconductor nanorod is a structural member made of a semiconductor and having a diameter of several hundred nm or less and a length of several μm or less. The semiconductor nanorod is disposed on the surface of the substrate (mask pattern) so that its longitudinal axis is generally perpendicular to the surface. Each semiconductor nanorod has at least the central nanorod, a first cover layer covering the central nanorod, and a second cover layer covering the first cover layer. The central nanorod extends upward from the substrate surface through the opening of the mask pattern. The central nanorod is formed of a semiconductor of a first conduction type (n-type or p-type). The first cover layer is formed of an intrinsic semiconductor. The second cover layer is formed of a semiconductor of a second conduction type (p-type or n-type) different from the first conduction type. That is, the central nanorod (n-type or p-type semiconductor), the first cover layer (intrinsic semiconductor) and the second cover layer (p-type or n-type semiconductor) form a p-i-n junction.

It is demanded that the central nanorod also function as a conductor. It is, therefore, preferable that the thickness (diameter) of the central nanorod be 10 nm or more, i.e., large enough to avoid depletion of carriers taking part in electrical conduction. As mentioned above, it is preferable that if the semiconductor nanorod includes a heterojunction, the thickness (diameter) of each semiconductor nanorod be within the range in which the generation density of crystal dislocations is minimized. Also, from the viewpoint of absorbing incident light by means of the plurality of disposed semiconductor nanorods so that a waste of incident light is minimized, it is preferable to design the length of the semiconductor nanorods by considering the light absorption coefficient of the semiconductor material. From these viewpoints, it is preferable that the thickness (diameter) of the central nanorods be within the range from 10 to 300 nm. Also, it is preferable that the length of the central nanorod be within the range from 0.5 to 10 μm.

Because the first cover layer and the second cover layer are formed outside the central nanorod, it is preferable to form the first cover layer and the second cover layer so that the generation of dislocations as a crystal defect is minimized. It is also preferable to form the first cover layer and the second cover layer so that each adjacent pair of semiconductor nanorods does not contact each other. Further, if the second cover layer is positioned at the outermost surface of each semiconductor nanorod, it is demanded that the second cover layer have a low electrical resistance and be capable of allowing a sufficient quantity of light to pass therethrough to the first cover layer positioned inside the second cover layer.

From these viewpoints, it is preferable that the film thickness of the first cover layer be within the range from 10 to several hundred nm. Also, it is preferable that the film thickness of the second cover layer be within the range from 10 to 100 nm.

Each of the semiconductor materials of the central nanorod, the first cover layer and the second cover layer may be any of a single semiconductor, a semiconductor formed of two constituent elements, a semiconductor formed of three constituent elements, a semiconductor formed of four constituent elements and a semiconductor formed of five or more constituent elements. Examples of the single semiconductor include Si and Ge. Examples of the semiconductor formed of two constituent elements include GaAs, InP, InAs, GaN, ZnS, ZnO, SiC, SiGe and ZnTe. Examples of the semiconductor formed of three constituent elements include AlGaAs, InGaAs, GaAsP, GaInP, AlInP, InGaN, AlGaN, ZnSSe and GaNAs. Examples of the semiconductor formed of four constituent elements include InGaAsP, InGaAlN, AlInGaP and GaInAsN.

The central nanorod may be formed of a single semiconductor and may have a tandem structure. For example, the central nanorod may have a tandem structure of a first region formed of a first semiconductor, a second region formed of a second semiconductor and a third region formed of a third semiconductor. The central nanorod may alternatively have a tandem structure of a first region formed of a first semiconductor, a second region formed of a second semiconductor, a third region formed of a third semiconductor and a fourth region formed of a fourth semiconductor. Needless to say, the central nanorod may alternatively have a tandem structure formed of five or more regions. In a case where the central nanorod has a tandem structure as described above, it is preferable that the semiconductor constituting a region closer to the transparent electrode side have a larger energy bandgap. That is, in a case where the first region, the second region, the third region and the fourth region are connected in this order from the substrate side, it is preferable that the fourth semiconductor has an energy bandgap larger than that of the third semiconductor; the energy bandgap of the third semiconductor is larger than that of the second semiconductor; and the energy bandgap of the second semiconductor is larger than that of the first semiconductor.

The solar cell element of the present invention has the first cover layer (i-layer) formed of an intrinsic semiconductor. The first cover layer is characterized by having two or more quantum barrier layers and a quantum well layer sandwiched between the quantum barrier layers or having two or more quantum barrier layers and a buried layer sandwiched between the quantum barrier layers and containing quantum dots. Each of the semiconductors constituting the quantum barrier layer, the quantum well layer, the quantum dots and the buried layer (the portion other than the quantum dots) is an intrinsic semiconductor. However, the energy bandgap of the semiconductor constituting the quantum well layer or the quantum dots is smaller than that of the semiconductor constituting the quantum barrier layer. The thickness of the quantum barrier layer may be, for example, within the range from 0.5 to several ten nm. The thickness of the quantum well layer may be, for example, within the range from 1 to several ten nm. The thickness of the buried layer may be, for example, within the range from 1 to several ten nm. Also, the energy bandgap of the semiconductor constituting the quantum dots is smaller than that of the semiconductor constituting the portion of the buried layer other than the quantum dots. The provision of the thus-formed first cover layer enables utilization for power generation of light having energy smaller than the energy bandgaps of the central nanorod (n-layer or p-layer), the first cover layer (i-layer) and the second cover layer (p-layer or n-layer).

One buried layer or two or more buried layers may be provided as the buried layer including a quantum well layer or quantum dots. In a case where two or more quantum well layers or buried layers are provided, the layers may be identical in composition to each other or different in composition from each other. For example, larger quantum dots may be buried in the buried layer closer to the central nanorod and smaller quantum dots may be buried in the buried layer remoter from the central nanorod. By adjusting the energy bandgaps, light can be converted into electricity with improved efficiency.

The shape of the quantum dots is not particularly specified if the movement of electrons or positive holes confined in the quantum dots is three-dimensionally repressed (limited). Examples of the shape of the quantum dots include a spherical shape, the shape of a one-side-convex lens and a tetrahedral shape. In a case where the shape of the quantum dots is spherical or tetrahedral, the size of the quantum dots in each of the three-dimensional directions may be within the range from several nm to 10 nm. In a case where the quantum dots has the shape of a one-side-convex lens, the size of the quantum dots may be within the range from 10 to 30 nm in width and depth and may be about several nm in height (thickness). If the quantum dots are distributed at a high density, and if the distance between the quantum dots is equal to or smaller than several nm, electrons or positive holes (holes) can move between adjacent pairs of the quantum dots by the tunnel effect.

Referring to FIG. 1, it is preferable that semiconductor nanorods 130 be arrayed in the form of a triangular lattice on the substrate (mask pattern). The triangular lattice is a lattice having lattice points corresponding to points of intersection of a plurality of straight lines parallel to the sides of a triangle T. The semiconductor nanorods 130 are disposed so that their centers coincide with the lattice points.

It can also be said that, in the above-described array, if the center-to-center distance between the semiconductor nanorods 130 is p, the semiconductor nanorods 130 are disposed in a hexagonal close-packed array with a unit pitch p, as indicated by the broken line in FIG. 1.

It is preferable that the semiconductor nanorods 130 be adjusted so that the ratio p/d of the center-to-center distance p between semiconductor nanorods and the minimum diameter d of the semiconductor nanorods 130 is within the range from 1 to 7, preferably from 1.5 to 5. By arraying the semiconductor nanorods 130 in this way, the reflectance of the solar cell element as a whole to incident light is reduced and the quantity of light absorbed in the semiconductor nanorods 130 is increased in comparison with that in a film of a planar structure. As a result, the solar cell element of the present invention is capable of increasing the power generation efficiency by reducing the photoreflectance while increasing the photoabsorbance.

The first electrode is connected to lower portions (lower ends) of the semiconductor nanorods, while the second electrode is connected to upper portions (ends) of the semiconductor nanorods. For connection of the first electrode to the lower portions (lower ends) of the semiconductor nanorods, the first electrode may be connected to a substrate having electrical conductivity. The first electrode is, for example, a metal electrode. The second electrode is, for example, a transparent electrode connected to the upper portions of the semiconductor nanorods and a metal electrode connected to the transparent electrode. The metal electrode is, for example, Ti/Au alloy film or Ge/Au/Ni/Au alloy film. The transparent electrode is, for example, InSnO film, SnSbO film or ZnO film.

It is preferable that the solar cell element of the present invention further have a surface protective layer covering the semiconductor nanorods. The surface protective layer covers the outermost layers (for example, the second cover layers) of the semiconductor nanorods. The material of the surface protective layer is not particularly specified if it has an energy bandgap larger than the energy bandgaps of all the semiconductors constituting the semiconductor nanorods.

In the solar cell element of the present invention, the gaps between the semiconductor nanorods may be filled with an insulating material. Examples of the insulating material include SOG glass and BCB resin.

The solar cell element of the present invention can utilize for power generation even light having small energy because it has the buried layer including the quantum well layer or the quantum dots.

The solar cell element of the present invention can be manufactured by any method as long as the effects of the present invention are not impaired. For example, the solar cell element of the present invention can be manufactured by a method including steps described below.

In the first step, a substrate whose surface is covered with a mask pattern having openings is prepared. For example, an insulating film may be formed by sputtering on the crystal axis (111) plane of a semiconductor crystal substrate and openings may be thereafter formed in the insulating film by photolithography, electron beam lithography or the like.

In the second step, central nanorods formed of a semiconductor of the first conduction type (n-type or p-type) are formed by crystal growth from the surface of the substrate through the openings of the mask pattern. The central nanorods are formed, for example, by metal organic chemical vapor deposition (MOCVD), molecular beam epitaxy (MBE), chemical vapor deposition (CVD) or the like. Preferably, the semiconductor nanorods are grown by MOCVD.

Forming of the central nanorods by MOCVD can be performed by using an ordinary MOCVD apparatus. That is, a raw material gas may be supplied at a predetermined temperature and a predetermined pressure to the substrate placed in a reactor. The central nanorods can be formed, for example, by a process described below. The growth of the nanorods is inhibited by the mask pattern in regions other than the openings.

First, the substrate temperature is set to 750° C. and gas of a metal organic material is supplied to the reactor, thereby forming the nanorods. The thickness (diameter) of the nanorods at this time is approximately the same as the diameter of the openings of the mask pattern. The nanorods extend in a direction perpendicular to the surface of the substrate. Then, to accelerate the growth in the radial direction of the nanorods in comparison with the growth in the lengthwise direction of the nanorods, the substrate temperature is reduced by about 50 to 100° C. to be set within the range from 650 to 700° C. At this temperature, the speed of growth at the side surfaces of the nanorods is higher than the speed of growth in the lengthwise direction of the nanorods. The ratio of the speed of growth in the lengthwise direction of the nanorods and the speed of growth in the radial direction of the nanorods can be changed to about 1:100 by reducing the substrate temperature to about 650° C. In this way, lateral growth can be achieved such that a shell portion is formed around a core portion of each nanorod. As the substrate temperature is increased from 650° C., the ratio of the lengthwise growth speed and the radial growth speed of the nanorods gradually becomes closer to 1. When the substrate temperature is within the range from 680 to 720° C., the ratio of the lengthwise growth speed and the radial growth speed of the nanorods are substantially equal to each other and crystals grow in such a manner as to envelop the surfaces of the nanorods. The growth speeds in the lengthwise and lateral directions can be controlled by changing the substrate temperature as described above.

The growth speeds in the lengthwise and lateral directions can also be controlled by changing the supply ratio V/III of V-group raw material gas and III-group raw material gas in supplied gases while controlling the substrate temperature. For example, to increase the growth speed in the lengthwise direction of GaAs nanorods at 750° C., the V/III supply ratio may be set in the range from 10 to 200. To reduce the growth speed in the lengthwise direction relative to the value reached in this way, the V/III supply ratio may be set in a higher range from 300 to 500, or set to 500 or higher. In this way, the growth speed in the lengthwise direction can be restricted within the range from several % to several ten %. At 650° C. suitable for growth in the radial direction of the nanorods, the growth in the lengthwise direction can be inhibited substantially completely if the V/III supply ratio is set to 300 or higher. On the other hand, when the V/III supply ratio is reduced to 100 or less, e.g., about 10, the growth speed in the lengthwise direction is higher than that when the V/III supply ratio is 300, but it is about an order of magnitude smaller than that in the case of growth at 750° C. The temperature ranges for selecting the shape of nanorods in forming the nanorods have been described with respect to GaAs nanorods by way of example. However, the same principle holds for nanorods formed of other semiconductors. In the case of forming AlGaAs nanorods, the temperature may be set to values about 50 to 100° C. higher than those in the case of GaAs nanorods. In the case of forming InAs nanorods or InGaAs nanorods, the temperature may be set to values about 100 to 200° C. lower than those in the case of GaAs nanorods.

For example, in the case of growing central nanorods formed of GaAs, trimethylgallium ((CH₃)₃Ga: TMG) gas may be supplied at a pressure of 1×10⁻⁶ to 1×10⁻⁵ atm as a gallium raw material, and arsenic hydride (AsH₃: arsine) gas may be supplied at a pressure of 1×10⁻⁵ to 1×10⁻³ atm as an arsenic raw material. In the case of growing central nanorods formed of AlGaAs, trimethylgallium gas, arsenic hydride gas and trimethylaluminum ((CH₃)₃Al: TMA) gas may be supplied as a gallium raw material, an arsenic raw material and an aluminum raw material, respectively. In the case of growing central nanorods formed of InGaAs, trimethylindium ((CH₃)₃In: TMI) gas, trimethylgallium gas and arsenic hydride gas may be supplied as an indium raw material, a gallium raw material and an arsenic raw material, respectively. In the case of growing central nanorods formed of InGaP, trimethylindium gas, trimethylgallium gas and tertiary butyl phosphine (TBP) gas may be supplied as an indium raw material, a gallium raw material and a phosphorus raw material, respectively. In the case of growing central nanorods formed of InGaP, the pressure at which tertiary butyl phosphine is supplied is set in the range from 1×10⁻⁴ to 1×10⁻³ atm and the growth temperature is set in the range from 700 to 750° C.

To make the semiconductor constituting the central nanorods n-type or p-type, n-type monosilane (SiH₄) gas or p-type dopant gas (e.g., dimethylzinc (Zn(CH₃)₂: DMZ) gas) may be supplied simultaneously with the raw material gas.

To form central nanorods in a tandem structure, the kinds of raw material gas to be supplied may be changed in the process of growing the central nanorods. For example, to form central nanorods having a structure in which GaAs, AlGaAs and GaInP are stacked in this order from the substrate side in the lengthwise direction, a process may be performed in which GaAs is grown at 750° C.; AlGaAs is subsequently grown at 800 to 820° C.; and GaInP is subsequently grown at 750 to 800° C. To form central nanorods having a structure in which Ge, GaAs, GaAsP and GaInP are stacked in this order from the substrate side in the lengthwise direction, a process may be performed in which Ge is grown at 600 to 650° C. by using germanium tetrahydride (Gelid gas as a germanium raw material; GaAs is subsequently grown at 750° C. by using trimethylgallium gas and arsenic hydride gas; GaAsP is subsequently grown at 780 to 800° C. by using trimethylgallium gas, arsenic hydride gas and tertiary butyl phosphine gas; and GaInP is subsequently grown at 750° C. by using trimethylgallium gas, trimethylindium gas and tertiary butyl phosphine gas.

In the third step, the first cover layer formed of an intrinsic semiconductor is formed around each central nanorod. That is, a core shell structure having the central nanorod as a core portion and the first cover layer as a shell portion is formed. The first cover layer may be formed by the same method (MOCVD, MBE, CVD or the like) as that for forming the central nanorod. The third step for forming the first cover layer includes a step of forming the quantum barrier layers by supplying gas of a first composition and a step of forming the quantum well layer or quantum dots by supplying gas of a second composition. Since it is necessary to set the potential of the quantum well layer or the quantum dots smaller than the potential of the surrounding quantum barrier layer, there is a need to make the material of the quantum well layer or quantum dots and the material of the quantum barrier layer different from each other. In the quantum well layer forming step, therefore, the composition of the metal organic raw material gas supplied to the reactor is changed. In a case where a heterojunction is formed, the kinds of raw material gas may be changed in the process of growing the semiconductor nanorods.

In the case of forming the quantum well layer, the thickness of the quantum well layer is reduced relative to the thickness of the nanorod and set in the range from 1 to 10 nm. To set the thickness of the quantum well layer in this range, the growth time may be set in the range from several seconds to about one minute. The raw material gas supply pressure may be set approximately equal to the supply pressure at the time of forming the central nanorod (core portion) or the supply pressure at the time of forming the shell portion. Also, the substrate temperature may be set approximately equal to that at the time of forming the shell portion.

In the case of forming InAs quantum dots, the substrate temperature may be set in the range from 400 to 500° C. and the growth time may be set in the range from about one to several ten seconds. The shorter the growth time, the smaller the size of the quantum dots can be. The raw material gas supply rate (supply pressure) may be about the same as that at the time of growing the core portion or the shell portion. When the growth temperature is closer to 400° C. in this temperature range, InAs crystal can be formed in land form on the GaAs surface. As the growth temperature is increased, the surface movement of the raw material gas attached to the substrate surface or the crystal surface becomes so active that the growth mode changes from the crystal in land form to growth in film form. Such forming of quantum dots is due to a difference in crystal lattice constant between InAs and GaAs. Therefore, InAs quantum dots can be formed by using any of semiconductors (e.g., InP and InGaN) capable of utilizing a difference in crystal lattice constant from InAs, not limited to GaAs. Forming of InGaAs quantum dots can also be performed on the basis of the same principle as that on which forming of InAs quantum dots is based. In this case, InGaAs quantum dots are formed on a semiconductor (e.g., GaAs or AlGaAs) having an energy bandgap larger than that of InGaAs. The optical growth temperature for InGaAs quantum dots is in the range from 500 to 600° C.

In the fourth step, the second cover layer is formed around the first cover layer. The second cover layer is formed of a semiconductor of the second conduction type. That is, if the central nanorod is of the n-type, the second cover layer is of the p-type. If the central nanorod is of the p-type, the second cover layer is of the n-type. The second cover layer may be formed by MOCVD, MBE, CVD or the like. In forming the second cover layer, n-type or p-type dopant gas may be supplied together with the raw material gas.

The shape of the openings of the mask pattern has substantially no influence on a section of each semiconductor nanorod perpendicular to the growth direction. Therefore, semiconductor nanorods having a shape substantially the same as the shape of a hexagonal prism can be obtained regardless of which one of triangular, hexagonal and circular shapes the openings have. The thickness of the semiconductor nanorods can also be controlled through the size (diameter) of the openings.

The solar cell element of the present invention can be manufactured by connecting the first electrode to the lower ends of the formed semiconductor nanorods and connecting the second electrode to the upper ends of the formed semiconductor nanorods. Ordinarily, the second electrode is a transparent electrode.

The semiconductor nanorods have an elongated shape whose diameter is several hundred nm or less and are therefore capable of reducing strain in the crystal lattice caused at the semiconductor junction interface. This effect is advantageous in forming a heterojunction having a large difference in lattice constant. For example, in a case where a heterojunction is formed in the longitudinal direction of each nanorod, strain in the crystal lattice is caused at the junction interface between the semiconductors having lattice constants different from each other. In solar cell elements of the conventional film structure, preventing the development of this strain in the crystal lattice into a crystal dislocation required making the semiconductor film extremely thin in thickness or reducing the difference in lattice constant. On the other hand, in the solar cell element of the present invention, the crystal lattice of the semiconductor nanorod is expandable in the outward direction and, therefore, strain in the crystal lattice hardly develops into a crystal dislocation. Thus, in the solar cell element of the present invention, a plurality of superlattice structures (quantum well layers or quantum dots) are included and the occurrence of dislocations in the semiconductor nanorod can be prevented even in a case where a heterojunction is formed such that the adjacent pair of superlattices are in close proximity to each other.

2. Color Sensor

A color sensor of the present invention has a substrate, a mask pattern sectioned into three or more regions, two or more semiconductor nanorods, a first electrode and a second electrode. One feature of the color sensor of the present invention resides in that semiconductor nanorods have different compositions in correspondence with the regions of the mask pattern, as described below.

The substrate is not particularly specified if it is capable of growing semiconductor nanorods. Examples of the material of the substrate include a semiconductor, a glass, a metal, a plastic, and a ceramic. Examples of the semiconductor constituting the substrate include GaAs, InP, Si, InAs, GaN, SiC and Al₂O₃. A semiconductor substrate is preferable, because forming semiconductor nanorods from the surface of the semiconductor substrate is easier to perform.

The mask pattern is a thin film disposed on the substrate surface and having two or more openings. If the substrate is a semiconductor crystal substrate, it is preferable that the mask pattern be disposed on the crystal axis (111) plane of the semiconductor crystal constituting the substrate. By growing a central nanorod in each semiconductor nanorod from the crystal axis (111) plane, the direction of extension of the central nanorod can be aligned with the crystal axis (111) plane of the semiconductor crystal. The material of the mask pattern is not particularly specified if it is capable of inhibiting the growth of the central nanorod in the semiconductor nanorod. Examples of the material of the mask pattern include an inorganic insulating material, a metal, a plastic, a ceramic and a combination of these materials. Examples of the inorganic insulating material include SiO₂ and SiN. Examples of the metal include W, WSi, Ti, Mo, Pt, MoSi, Ni, NiSi, WAl, TiAl and MoAl. The film thickness of the mask pattern is not particularly specified. A mask pattern film thickness of several nanometers or more may suffice. The film thickness of the mask pattern may be equal to the length of the semiconductor nanorod (about several microns).

As mentioned above, the mask pattern is sectioned into three or more regions. Ordinarily, the regions respectively correspond to red light, green light and blue light, abbreviated as “RGB”, herein. Two or more openings are formed in each region of the mask pattern. The openings are formed therethrough to reach the substrate surface. The substrate surface is exposed in the openings. With the openings, in manufacture of the color sensor of the present invention, the position at which the central nanorod in each semiconductor nanorod is grown and the thickness and the shape of the central nanorod are specified. The openings may have any shape, e.g., a circular, triangular, rectangular or a hexagonal shape. The size (diameter) of the openings may be within the range from 10 nm or to several hundred nm. The center-to-center distance between the openings may be 5 μm or less. It is preferable that the diameter of the openings and the center-to-center distance between the openings be constant in one region. On the other hand, it is preferable that the diameter of the openings and the center-to-center distance between the openings be set different from each other on a region-by-region basis.

Each semiconductor nanorod is a structural member formed of InGaN and having a diameter of several hundred nm or less and a length of several μm or less. The semiconductor nanorod is disposed on the surface of the substrate (mask pattern) so that its longitudinal axis is generally perpendicular to the surface. Each semiconductor nanorod has at least the central nanorod and a first cover layer covering the central nanorod, and has a p-n junction or a p-i-n junction. The central nanorod extends upward from the substrate surface through the opening of the mask pattern. The central nanorod is formed of a semiconductor of a first conduction type (n-type or p-type). The first cover layer is formed of InGaN which is of a second conduction type (p-type or n-type) different from the first conduction type. That is, the central nanorod (n-type or p-type InGaN) and the first cover layer (p-type or n-type InGaN) form a p-n junction or a p-i-n junction. The diameter of the central nanorod may be within the range from 10 to 200 nm, and the length of the central nanorod may be within the range from 0.5 to 3 μM. The film thickness of the first cover layer may be within the range up to 100 nm.

The semiconductor nanorods have different compositions according to the wavelengths of light to be detected in correspondence with the regions of the mask pattern. That is, the semiconductor nanorod in the region for detecting red light has such a composition as to be capable of absorbing red light; the semiconductor nanorod in the region for detecting green light has such a composition as to be capable of absorbing green light; and the semiconductor nanorod in the region for detecting blue light has such a composition as to be capable of absorbing blue light. A concrete example of the composition will be described in the description of a manufacturing method.

The first electrode is connected to lower portions (lower ends) of the semiconductor nanorods, while the second electrode is connected to upper portions (upper ends) of the semiconductor nanorods. For connection of the first electrode to the lower portions (lower ends) of the semiconductor nanorods, the first electrode may be connected to the substrate having electrical conductivity. The first electrode is, for example, a metal electrode. The second electrode is, for example, a transparent electrode connected to the upper portions of the semiconductor nanorods and a metal electrode connected to the transparent electrode. The metal electrode is, for example, Ti/Au alloy film or Ge/Au/Ni/Au alloy film. The transparent electrode is, for example, InSnO film, SnSbO film or ZnO film.

In the color sensor of the present invention, the gaps between the semiconductor nanorods may be filled with an insulating material. Examples of the insulating material include SOG glass and BCB resin.

The color sensor of the present invention is used by applying a reverse bias to the p-n junction. The color sensor of the present invention has superior detection sensitivity because of its low photoreflectance.

The color sensor of the present invention can be manufactured by any method as long as the effects of the present invention are not impaired. For example, the color sensor of the present invention can be manufactured by a method including steps described below.

In the first step, a substrate whose surface is covered with a mask pattern having openings is prepared. For example, an insulating film may be formed by sputtering on the crystal axis (111) plane of a semiconductor crystal substrate and openings may be thereafter formed in the insulating film by photolithography or electron beam lithography. As mentioned above, the mask pattern is sectioned into three or more regions. It is preferable to change the diameter of the openings and/or the center-to-center distance between the openings with respect to the regions of the mask pattern in order to change the composition of the semiconductor nanorods with respect to the regions of the mask pattern, as described below.

In the second step, central nanorods formed of InGaN of the first conduction type (n-type or p-type) are formed by crystal growth from the surface of the substrate through the openings of the mask pattern. The central nanorods are formed, for example, by metal organic chemical vapor deposition (MOCVD), molecular beam epitaxy (MBE), chemical vapor deposition (CVD) or the like. Preferably, the semiconductor nanorods are grown by MOCVD.

Forming of the central nanorods by MOCVD can be performed by using an ordinary MOCVD apparatus. That is, a raw material gas may be supplied at a predetermined temperature and a predetermined pressure to the substrate placed in a reactor. The central nanorods can be formed, for example, by a process described below. The growth of the nanorods is inhibited by the mask pattern in regions other than the openings.

First, the substrate temperature is set to 750° C. and gas of an metal organic material is supplied to the reactor, thereby forming the nanorods. Trimethylindium gas can be used as an indium raw material. Trimethylgallium gas can be used as a gallium raw material. Ammonia gas can be used as a nitrogen raw material. The thickness (diameter) of the nanorods at this time is approximately the same as the diameter of the openings of the mask pattern. The nanorods extend in a direction perpendicular to the surface of the substrate. To change the semiconductor constituting the central nanorods into the n-type or the p-type, n-type monosilane gas or p-type dopant gas (e.g., dimethylzinc gas) may be supplied simultaneously with the raw material gas.

In crystal growth of InGaN, the ratio of In and Ga in InGaN can be controlled by changing the ratio of the In raw material gas supply rate (supply pressure) and the Ga raw material gas supply rate (supply pressure). The ratio of In and Ga in InGaN can also be controlled by changing the substrate temperature during growth. Ordinarily, the substrate temperature is within the range from 600 to 1000° C. The higher the temperature, the smaller the amount of In taken in, and the Ga-richer the crystal composition.

In the color sensor of the present invention, as described above, the semiconductor nanorods as a whole have different compositions in correspondence with the regions of the mask pattern. In a three-component chemical compound semiconductor InₓGa₁₋ₓN, the optical energy bandgap decreases monotonously with increase in the content x of In. In GaN in which the content x of In is zero, the energy bandgap is about 3.4 eV, and the energy bandgap decreases as the content x of In is increased (while the content 1-x of Ga is reduced). In InN in which the content x of In is 1, the energy bandgap is about 0.8 eV. The energy bandgap corresponding to red light (wavelength 650 nm) is about 1.9 V; the energy bandgap corresponding to green light (wavelength 520 nm) is about 2.4 V; and the energy bandgap corresponding to blue light (wavelength 460 nm) is about 2.7 V. Accordingly, the values of the content x of In in InₓGa₁₋ₓN respectively corresponding to red light, green light and blue light are 0.5, 0.3 and 0.2.

For example, to change the composition of the semiconductor nanorods with respect to the regions of the mask pattern, the diameter of the openings and/or the center-to-center distance between the openings may be changed with respect to the regions of the mask pattern when the openings are formed in the mask pattern in the first step. Changes in composition of the central nanorods in crystal growth by MOCVD or MBE are explained below in relation to the substrate temperature when the nanorods are grown, the size of the openings of the mask pattern and the center-to-center distance between the openings. Description is made below by assuming that the size of the openings of the mask pattern is within the range from 50 to 500 nm, and that the center-to-center distance between the openings is within the range from 100 nm to 10 μm.

1) Relationship Between the Center-to-Center Distance Between Openings and the Composition of Nanorods (Preliminary Experiment).

Three mask pattern regions A, B, and C were formed on one substrate. The size of each region was set to 100 μm×100 μm; the distance between each adjacent pair of the mask pattern regions was set to 100 μm; and the size of the openings was to about 100 nm. In the mask pattern region A, the center-to-center distance P between the openings was set to 0.5 μm. In the mask pattern region B, the center-to-center distance P between the openings was set to 2.0 μm. In the mask pattern region C, the center-to-center distance P between the openings was set to 5.0 μm. Each of parameters other than the center-to-center distance P between the openings was unchanged among the mask pattern regions A, B, and C.

When trimethylgallium gas, trimethylindium gas and ammonia gas are supplied at the substrate temperature 750° C. as a gallium raw material gas, an indium raw material gas and a nitrogen raw material, respectively, these gases cause thermal decomposition reaction in the vicinity of the substrate surface and decomposed elements (Ga, In and N) gather at the openings of the mask pattern by moving along the surface of the mask pattern. In the region covered with the mask pattern, crystal growth does not occur. Crystal growth occurs in the portions in the openings where the semiconductor crystal is exposed. Since the substrate is heated at the mask pattern surface, the elements and raw material gases attached to the surface separate scatter from the substrate surface into the gas phase after a lapse of a certain time period. The surface movement distance through which Ga moves along the surface of the mask pattern is longer than that of the surface movement distance through which In moves. In the elements attached at positions remote from the openings, therefore, the amount of Ga that reaches the openings is larger than the amount of In that reaches the openings. Thus, when the center-to-center distance P between the openings is large, a GaInN crystal is produced in which the Ga content is larger than the In content. On the other hand, when the center-to-center distance P between the openings is small (about 0.5 μm), the Ga surface movement distance and the In surface movement distance are each longer than the center-to-center distance P between the openings, and a GaInN crystal is produced in which the In content is larger than the Ga content. This principle also holds in the case of growing GaInN nanorods. When the substrate temperature is increased, the amount of In taken in is reduced relative to Ga. When the substrate temperature is reduced, the amount of In taken in is increased relative to Ga. It is, therefore, preferable to control the substrate temperature as well in order to largely change the ratio of Ga and In in GaInN.

Nanorods were grown by setting the rate of supply of trimethylgallium gas to 0.1 mol/min, the rate of supply of trimethylindium gas to 0.1 mol/min and the rate of supply of ammonia gas to 2000 cc/min. Optical characteristics of the nanorods were measured using photoluminescence. Through this measurement, orange emission (wavelength 590 nm) was observed through the mask pattern region A (P=0.5 μm); green emission (wavelength 510 nm) was observed through the mask pattern region B (P=2 μm); bluish green emission (wavelength 495 nm) was observed through the mask pattern region C(P=5 μm).

2) Relationship Between the Size of Openings and the Composition of Nanorods (Preliminary Experiment)

Two mask pattern regions A and B were formed on one substrate. The size of each region was set to 100 μm×100 μm; the distance between each adjacent pair of the mask pattern regions was set to 100 μm; and the size of the openings was to 0.5 μm. In the mask pattern region A, the size d of the openings was set to 100 nm. In the mask pattern region B, the size d of the openings was set to 300 nm. Each of parameters other than the size d of the openings was unchanged between the mask pattern regions A and B.

Nanorods were grown by setting the rate of supply of trimethylgallium gas to 0.1 mol/min, the rate of supply of trimethylindium gas to 0.1 mol/min and the rate of supply of ammonia gas to 2000 cc/min. Optical characteristics of the nanorods were measured using photoluminescence. As a result, orange emission (wavelength 590 nm) was observed through the mask pattern region A (d=100 nm) and red emission (wavelength 630 nm) was observed through the mask pattern region B (d=300 nm).

According to the results of the above-described preliminary experiments, GaInN nanorods corresponding to red light, green light and blue light can be formed by setting the center-to-center distance P between the openings and the opening size d in the mask pattern formed on the substrate as shown below.

GaInN nanorod having a sensitivity center peak in the red wavelength band:

P=0.5 to 0.7 μm, d=400 to 500 nm ii) GaInN nanorod having a sensitivity center peak in the green wavelength band:

P=2 to 3 μm, d=100 to 200 nm

iii) GaInN nanorod having a sensitivity center peak in the blue wavelength band:

P=5 to 7 μm, d=100 nm

In the second step, the first cover layer is formed around the central nanorod. The first cover layer is formed of InGaN of the second conduction type. That is, if the central nanorod is of the n-type, the first cover layer is of the p-type. If the central nanorod is of the p-type, the first cover layer is of the n-type. By forming the first cover layer, a p-n junction is formed in the semiconductor nanorods in the lengthwise direction and/or in the radial direction. The first cover layer may be formed by MOCVD, MBE, CVD or the like. In forming the first cover layer, n-type or p-type dopant gas may be supplied together with the raw material gas.

The shape of the openings of the mask pattern has no influence on a section of each semiconductor nanorod perpendicular to the growth direction. Therefore, semiconductor nanorods having a shape substantially the same as the shape of a hexagonal prism can be obtained regardless of which one of triangular, hexagonal and circular shapes the openings have. The thickness of the semiconductor nanorods can also be controlled through the size (diameter) of the openings.

The color sensor of the present invention can be manufactured by connecting the first electrode to the lower ends of the formed semiconductor nanorods and connecting the second electrode to the upper ends of the formed semiconductor nanorods. Ordinarily, the second electrode is a transparent electrode.

3. Method of Manufacturing Light Emitting Element and Light Receiving Element

A manufacturing method of the present invention is a method of simultaneously forming a light emitting element and a light receiving element. This method has A) a first step of preparing a substrate whose surface is covered with a mask pattern and B) a second step of growing semiconductor nanorods through openings from the substrate covered with the mask pattern.

In the first step, a substrate whose surface is covered with a mask pattern having openings is prepared. For example, an insulating film may be formed by sputtering on the crystal axis (111) plane of a semiconductor crystal substrate and openings may be thereafter formed in the insulating film by photolithography or electron beam lithography. At this time, the mask pattern is sectioned into a region where a light emitting element is formed and a region where a light receiving element is formed. It is preferable to change the size of the openings and/or the center-to-center distance between the openings between the light emitting element forming region and the light receiving element forming region in order that semiconductor nanorods included in the light emitting element and semiconductor nanorods included in the light receiving elements have different compositions as described below.

In the second step, semiconductor nanorods are grown from the substrate through the openings of the mask pattern. At this time, a layer formed of an n-type semiconductor and a layer formed of a p-type semiconductor are formed in the semiconductor nanorods to form a p-n junction or a p-i-n junction. The semiconductor constituting the semiconductor nanorods is GaInN or GaInAs. Forming of the semiconductor nanorods is performed, for example, by metal organic chemical vapor deposition (MOCVD), molecular beam epitaxy (MBE), chemical vapor deposition (CVD) or the like. Preferably, the semiconductor nanorods are grown by MOCVD.

Forming of the semiconductor nanorods by MOCVD can be performed by using an ordinary MOCVD apparatus. That is, a raw material gas may be supplied at a predetermined temperature and a predetermined pressure to the substrate placed in a reactor. The semiconductor nanorods can be formed, for example, by a process described below. The growth of the nanorods is inhibited by the mask pattern in regions other than the openings.

Description will be made below of a case where GaInN is grown. First, the substrate temperature is set to 675° C. and gas of an metal organic material is supplied to the reactor, thereby forming the nanorods. For example, trimethylindium gas can be used as an indium raw material; trimethylgallium gas can be used as a gallium raw material; and ammonia gas can be used as a nitrogen raw material. The thickness (diameter) of the nanorods at this time is approximately the same as the diameter of the openings of the mask pattern. The nanorods extend in a direction perpendicular to the surface of the substrate. To make the semiconductor constituting the central nanorods n-type or p-type, n-type monosilane gas or p-type dopant gas (e.g., dimethylzinc gas) may be supplied simultaneously with the raw material gas.

In crystal growth of InGaN, the ratio of In and Ga in InGaN can be controlled by changing the ratio of the In raw material gas supply rate (supply pressure) and the Ga raw material gas supply rate (supply pressure). The ratio of In and Ga in InGaN can also be controlled by changing the substrate temperature during growth. Ordinarily, the substrate temperature is within the range from 600 to 1000° C. The higher the temperature, the smaller the amount of In taken in, and the Ga-richer the crystal composition. On the other hand, the lower the temperature, the smaller the amount of Ga taken in, and the In-richer the crystal composition.

The semiconductor nanorod composition in the light emitting element and the semiconductor nanorod composition in the light receiving element are different from each other. Also, in the light emitting element, the composition of the semiconductor nanorods is changed with respect to emission wavelengths. In the light emitting element, the mask pattern is sectioned into the number of the emission wavelengths. That is, in a case where four different wavelengths of light are emitted, the mask pattern in the light emitting element is sectioned into four. In each region, the composition of the semiconductor nanorods is adjusted so that the semiconductor nanorods emit the desired wavelength of light. On the other hand, in the light receiving element, the composition of the semiconductor nanorods is adjusted so that the wavelengths of light emitted by the light emitting element can be received.

For example, to change the composition of the semiconductor nanorods with respect to the regions of the mask pattern, the size of the openings and/or the center-to-center distance between the openings may be changed with respect to the regions of the mask pattern when the openings are formed in the mask pattern in the first step. Changes in composition of the semiconductor nanorods in crystal growth by MOCVD or MBE are explained below in relation to the substrate temperature when the nanorods are grown, the size of the openings of the mask pattern and the center-to-center distance between the openings. Description is made below by assuming that the size of the openings of the mask pattern is within the range from 50 to 500 nm, and that the center-to-center distance between the openings is within the range from 100 nm to 10 μm.

2) Relationship Between the Center-to-Center Distance Between Openings and the Composition of Nanorods (Preliminary Experiment).

A plurality of mask pattern regions were formed on one substrate. The size of each region was set to 50 μm×50 μm; the distance between each adjacent pair of the mask pattern regions was set to 50 μm; and the size of the openings was to about 100 nm. The center-to-center distance L between the openings was changed from 0.5 to 5 μm with respect to the mask pattern regions. Each of parameters other than the center-to-center distance L between the openings was unchanged among the plurality of mask pattern regions.

Description will be made below of a case where GaInAs is grown. GaInAs nanorods were grown at the substrate temperature 675° C. by supplying trimethylgallium gas (supply pressure: 1.0×10⁻⁷ to 1.0×10⁻⁶ atm) as a gallium raw material gas, trimethylindium gas (supply pressure: 1.0×10⁻⁷ to 1.0×10⁻⁶ atm) as an indium raw material gas, arsenic hydride gas (supply pressure: 1.0×10⁻⁵ to 1.0×10⁻⁴ atm) as an arsenic raw material gas. Optical characteristics of the nanorods were measured using photoluminescence. The results were that, with the increase in center-to-center distance L between the openings from 0.5 to 3.0 μm, the energy bandgap in the GaInAs nanorods decreased generally monotonously from 1.35 eV (wavelength 918 nm) to 1.15 eV (wavelength 1078 nm). From this, it can be understood that the amounts of Ga and In taken in can be controlled by changing the center-to-center distance L between the openings. In particular, in the case of growing GaInAs nanorods, the amount of Ga taken in was increased when the center-to-center distance L between the openings was set to 1 μm or less. The same tendency was also observed in the case where the size of the openings is 50 nm, 200 nm or 500 nm.

2) Relationship Between the Size of Openings and the Composition of Nanorods (Preliminary Experiment)

A plurality of mask pattern regions were formed on one substrate. The size of each region was set to 50 μm×50 μm; the distance between each adjacent pair of the mask pattern regions was set to 50 μm; and the center-to-center distance between the openings was set to 1.0 μm. The size d of the openings was changed from 50 to 50 nm with respect to the mask pattern regions. Each of parameters other than the size d the openings was unchanged among the plurality of mask pattern regions.

GaInAs nanorods were grown by the same procedure as that described in 1) above. Optical characteristics of the nanorods were measured using photoluminescence. The results were that, with the increase in size d of the openings from 50 nm to 200 nm, the energy bandgap in the GaInAs nanorods changed slightly from 1.34 eV (wavelength 925 nm) to 1.32 eV (wavelength 939 nm). Also, with the increase in size d of the openings from 300 nm to 400 nm, the energy bandgap in the GaInAs nanorods changed slightly from 1.32 eV to 1.31 eV.

From the results of the preliminary experiments shown above, settings shown below of the center-to-center distance L between the openings and the opening size d in the mask pattern formed on the substrate, to be made for simultaneously making on the one substrate the light emitting element having a plurality of emission wavelengths and the light receiving element, are derived.

i) Light Emitting Element Having GaInAs Nanorods

The mask pattern in the light emitting element region is sectioned into four regions: a mask pattern region A, a mask pattern region B, a mask pattern region C and a mask pattern region D. The size d of the openings in each region is set to 100 nm. The center-to-center distance L between the openings of the mask pattern region A is set to 0.5 μm; the center-to-center distance L between the openings of the mask pattern region B is set to 1.0 μm; the center-to-center distance L between the openings of the mask pattern region C is set to 2.0 μm; and the center-to-center distance L between the openings of the mask pattern region D is set to 3.0 μm;

ii) Light Receiving Element Having GaInAs Nanorods

The center-to-center distance L between the openings of the mask pattern in the light receiving element region is set within the range from 3.0 to 10 thereby enabling a peak of the detection sensitivity of the light receiving element to be set to a wavelength equal to or longer than any of the wavelengths of light emitted by the light emitting element. The light receiving element having GaInAs nanorods has sensitivity to light having the same wavelength as the peak of the detection sensitivity and to light having shorter wavelengths (having larger energy). Therefore the light receiving element having GaInAs nanorods has sensitivity to all the wavelengths of light emitted by the light emitting element.

For example, GaInAs nanorods are grown at the substrate temperature 675° C. on the substrate with the mask pattern formed thereon in accordance with the above-described conditions by supplying trimethylgallium gas, trimethylindium gas and arsenic hydride gas to simultaneously make a light emitting element having emission wavelengths of 925 nm (mask pattern region A), 990 nm (mask pattern region B), 1040 nm (mask pattern region C) and 1090 nm (mask pattern region D) and a light receiving element capable of receiving light with wavelengths of 925 to 1090 nm.

The light emitting element and the light receiving element can be made by connecting the first electrode to the lower ends of the formed semiconductor nanorods and connecting the second electrode to the upper ends of the formed semiconductor nanorods. Ordinarily, the second electrode is a transparent electrode.

By applying a forward bias to the p-n junction, the light emitting element manufactured by the manufacturing method of the present invention can be caused to emit light. The light receiving element manufactured by the manufacturing method of the present invention can be used by applying a reverse bias to the p-n junction. The light emitting element manufactured by the manufacturing method of the present invention is applicable, for example, to an optical transmission system of a parallel transmission type or a wavelength multiplex type.

The method of manufacturing a light emitting element and a light receiving element according to the present invention enables simultaneously manufacturing a light emitting element and a light receiving element and, therefore, enables a light emitting element and a light receiving element to be manufactured at a reduced cost with improved efficiency in comparison with the conventional method.

The present invention will be described in more detail with reference to the drawings.

### First Embodiment

In a first embodiment of the present invention, an example of a semiconductor nanorod array used in the solar cell element of the present invention is illustrated.

FIG. 1 is a perspective view showing the construction of the semiconductor nanorod array in the first embodiment. As shown in FIG. 1, the semiconductor nanorod array in the first embodiment has an electroconductive GaAs(111)B substrate 110, an amorphous SiO₂ film 120 and semiconductor nanorods 130.

A method of manufacturing the semiconductor nanorod array shown in FIG. 1 will be described.

First, the GaAs(111)B substrate 110 is cleaned and the amorphous SiO₂ film 120 is formed to a thickness of about 20 nm on the surface of the GaAs(111)B substrate 110 by using an RF sputtering apparatus with a SiO₂ target.

Next, a positive resist is applied on the amorphous SiO₂ film 120; the GaAs(111)B substrate 110 is set in an EB drawing apparatus; and a pattern in which circular holes are arrayed in triangular lattice form is drawn on the positive resist. The circular holes correspond to circles inscribed in the semiconductor nanorods 130 each in the form of a regular hexagon as viewed in section in FIG. 1.

After drawing, the resist is developed and the GaAs(111)B substrate 110 is immersed in a 50 times diluted BHF solution to etch and remove SiO₂ in the circular holes. The resist is removed after the etching. As a result, a mask pattern formed of the amorphous SiO₂ film 120 is formed.

Next, the GaAs(111)B substrate 110 on which the mask pattern formed of the amorphous SiO₂ film 120 is formed is set in an MOVPE apparatus; the chamber is evacuated, followed by replacement with H₂ gas; and the flow rate and exhaustion speed are adjusted so that the total pressure is stabilized at 0.1 atm.

Next, the substrate temperature is increased to 750° C. while causing mixture gas of AsH₃ (arsine) and carrier gas (H₂) (total pressure: 0.1 atm, AsH₃ partial pressure: 2.5×10⁻⁴ atm) to flow. After the substrate temperature has reached 750° C., TMG (trimethylgallium) is added to the flown gas to grow the semiconductor nanorods 130 formed of GaAs. At this time, the total pressure is maintained at 0.1 atm; the AsH₃ partial pressure is set to 2.5×10⁻⁴ atm; and the TMG partial pressure is set to 1.0×10⁻⁶ atm.

Next, supply of TMG is stopped 30 minutes after addition of TMG to the flown gas, thereby terminating the growth of the semiconductor nanorods 130. The semiconductor nanorod array in which the semiconductor nanorods 130 have been grown under the mixture gas of AsH₃ (arsine) and carrier gas (H₂) is then taken out.

According to the above-described manufacturing method, the minimum diameter d of the semiconductor nanorods 130 (the diameter of the circle inscribed in the regular hexagonal section of the semiconductor nanorods 130) coincides with the diameter of the mask pattern circular holes. Therefore, the minimum diameter d of the semiconductor nanorods 130 can be controlled through the diameter of the mask pattern circular holes.

A plurality of semiconductor nanorod arrays were made by changing the minimum diameter d of the semiconductor nanorods 130 in the range from 50 to 300 nm and by changing the center-to-center distance between each adjacent pair of the semiconductor nanorods 130 in the range from 70 to 900 nm in the above-described manufacturing method. A reflectance spectrum when light was perpendicularly incident on each semiconductor nanorod array was measured with a spectrophotometer.

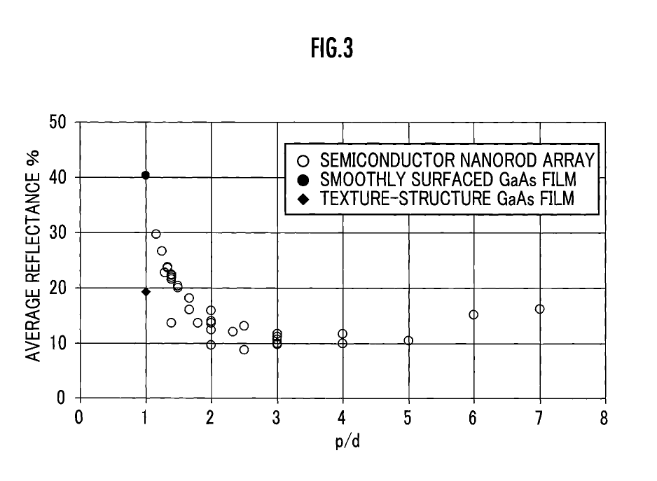

In the case of the semiconductor nanorods 130 formed of GaAs, the wavelengths of usable solar light is in the range from 300 to 900 nm. Therefore an average reflectance with respect to a ratio p/d was obtained in the range of 300 to 900 nm from the reflectance spectrum obtained by the above-described measurement. The ratio p/d is the ratio of the center-to-center distance p between the semiconductor nanorods 130 and the minimum diameter d of the semiconductor nanorods. FIG. 3 shows the results.

FIG. 3 also shows average reflectances obtained in the same manner as that of the above-described semiconductor nanorod array by using a smoothly surfaced GaAs film formed on a substrate and a texture-structure GaAs film with pits and projections formed on the surface in order to reduce reflection loss at the surface.

From FIG. 3, it is recognized that the average reflectance of the semiconductor nanorod array in the first embodiment is smaller than that of the smoothly surfaced GaAs film when p/d is in the range from 1 to 7, and is smaller than that of the texture-structure GaAs film when p/d is in the range from 1.5 to 7. It is also recognized that the average reflectance of the semiconductor nanorod array in the first embodiment is minimized when p/d is in the range from 1.5 to 5.

Thus, it is apparent that the semiconductor nanorod array in the first embodiment is capable of increasing the absorbance with respect to incident light by setting p/d in the range from 1 to 7 to improve the power generation efficiency.

### Second Embodiment

In a second embodiment of the present invention, an example of a solar cell element of the present invention having a plurality of quantum well layers is illustrated.

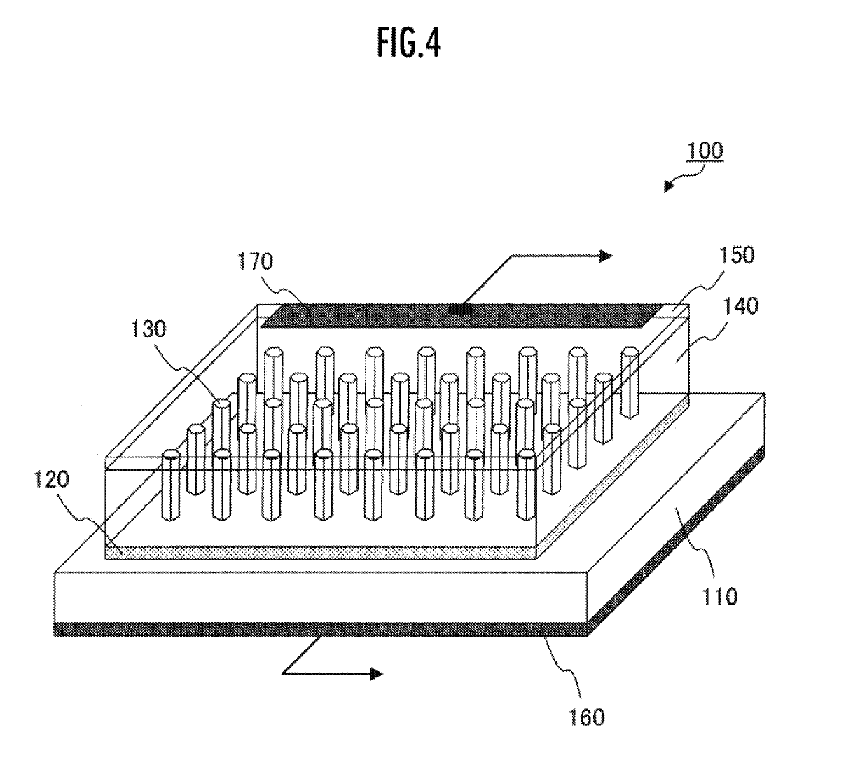

FIG. 4 is a perspective view showing the construction of the solar cell element in the second embodiment. As shown in FIG. 4, a solar cell element 100 in the second embodiment has an electroconductive GaAs substrate 110, a silicon oxide (SiO₂) film 120, semiconductor nanorods 130, a transparent embedment film 140, a transparent electrode 150, a first metal electrode 160 and a second metal electrode 170. The first electrode 160 and the second electrode 170 are connected to an external circuit.

The electroconductive GaAs substrate 110 is an electroconductive GaAs(111)B substrate.

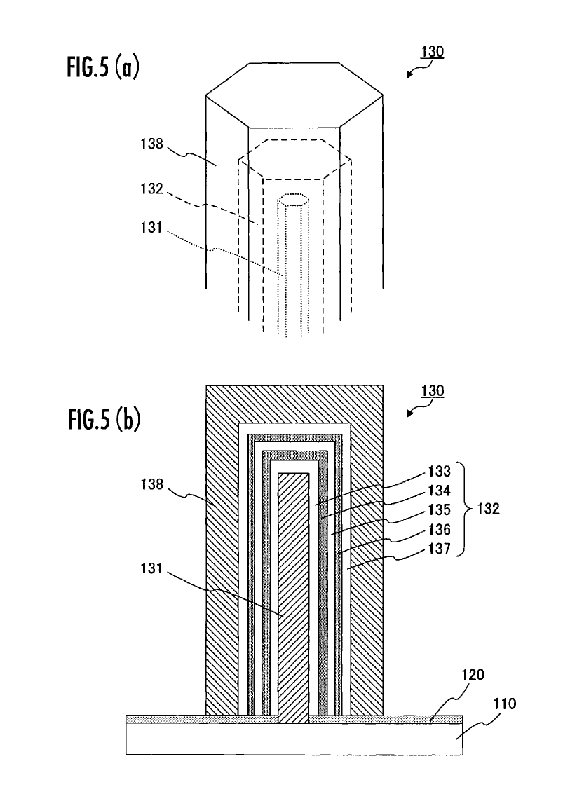

The SiO₂ film 120 covers the (111)B plane of the GaAs substrate 110. The film thickness of the SiO₂ film 120 is, for example, 20 nm. In regions of the SiO₂ film 120 where the semiconductor nanorods 130 are disposed, openings are formed through the SiO₂ film 120. As described below, n-type GaAs nanorods (central nanorods) 131 in the semiconductor nanorods 130 are in direct contact with the GaAs substrate 110 (see FIG. 5(b)).

A plurality of semiconductor nanorods 130 are disposed on the SiO₂ film 120 so that its longitudinal axis is generally perpendicular to the (111)B plane of the electroconductive GaAs substrate 110. The outside diameter of the semiconductor nanorods 130 is, for example, 200 nm, and the height of the semiconductor nanorods 130 from the SiO₂ film 120 surface is, for example, 1000 nm. The semiconductor nanorods 130 are arrayed so that the center-to-center distance p is, for example, 300 nm (see FIG. 1).

FIG. 5 is a diagram showing the structure of the semiconductor nanorod 130. FIG. 5(a) is a perspective view of the semiconductor nanorod 130, and FIG. 5(b) is a sectional view of the semiconductor nanorod 130. As shown in FIGS. 5(a) and 5(b), the semiconductor nanorod 130 has an n-type GaAs nanorod 131 (central nanorod), a nondoped GaAs layer (first cover layer) 132 covering the n-type GaAs nanorod 131 and having quantum well layers, and a p-type GaAs layer (second cover layer) 138 covering the nondoped GaAs layer 132. The n-type GaAs nanorod 131 functions as an n-layer; the nondoped GaAs layer 132 functions as an i-layer; and the p-type GaAs layer 138 functions as a p-layer. That is, the n-type GaAs nanorod 131, the nondoped GaAs layer 132 and the p-type GaAs layer 138 form a p-i-n junction. The thickness of the n-type GaAs nanorod 131 at the foot end is, for example, 100 nm, and the height of the n-type GaAs nanorod 131 from the surface of the GaAs substrate 110 is, for example, 800 nm.

As shown in FIG. 5(b), the nondoped GaAs layer 132 has two nondoped InGaAs quantum well layers. Each of these two nondoped InGaAs quantum well layers is sandwiched between nondoped GaAs quantum barrier layers. That is, the nondoped GaAs layer 132 has a first nondoped GaAs quantum barrier layer 133 covering the n-type GaAs nanorod 131; a first nondoped InGaAs quantum well layer 134 covering the first nondoped GaAs quantum barrier layer 133; a second nondoped GaAs quantum barrier layer 135 covering the first nondoped InGaAs quantum well layer 134; a second nondoped InGaAs quantum well layer 136 covering the second nondoped GaAs quantum barrier layer 135; and a third nondoped GaAs quantum barrier layer 137 covering the second nondoped InGaAs quantum well layer 136. The nondoped InGaAs quantum well layers 134 and 136 and the nondoped GaAs quantum barrier layers 133, 135, and 137 form a superlattice structure. Carriers can freely move in these nondoped InGaAs quantum well layers 134 and 136. If the film thickness of one quantum barrier layer is several nm or less, carriers in the two quantum well layers sandwiching the quantum barrier layer can move freely between the two quantum well layers by passing through the quantum barrier layer by the tunnel effect.

While the n-type GaAs nanorod (central nanorod) 131 is in contact with the (111)B plane of the electroconductive GaAs substrate 110 as mentioned above, each of the nondoped InGaAs quantum well layers 134 and 136 and the nondoped GaAs quantum barrier layers 133, 135, and 137 is not in contact with the (111)B plane of the electroconductive GaAs substrate 110. The film thickness of the first nondoped InGaAs quantum well layer 134 is, for example, 10 nm, and the film thickness of the second nondoped InGaAs quantum well layer 136 is, for example, 5 nm. The film thickness of each of the nondoped GaAs quantum barrier layers 133, 135, and 137 is, for example, 3 nm.

The transparent embedment film 140 is an insulating film covering the side surfaces of the semiconductor nanorods 130 and filling the space between the semiconductor nanorods 130. Upper portions of the semiconductor nanorods 130 are exposed without being covered with the transparent embedment film 140. Examples of the material of the transparent embedment film 140 include SOG glass and BCB resin.

The transparent electrode 150 is connected to the upper portions of the semiconductor nanorods 130 exposed without being covered with the transparent embedment film 140. The transparent electrode 150 is ohmic-connected to the p-type GaAs layers (second cover layers) 138 of the semiconductor nanorods 130. Examples of the material of the transparent electrode 150 include InSnO, SnSbO and ZnO.

The first metal electrode 160 is disposed on the surface of the electroconductive GaAs substrate 110 where the SiO₂ film 120 does not exist, and is ohmic-connected to the electroconductive GaAs substrate 110. Examples of the material of the first metal electrode 160 include metals such as Au and Ti.

The second metal electrode 170 is disposed on the transparent electrode 150 and ohmic-connected to the transparent electrode 150. Example of the material of the second metal electrode 170 include metals such as Au and Ti.

A method of manufacturing the solar cell element 100 in the second embodiment will be described with reference to the drawings.

First, the electroconductive GaAs substrate (GaAs(111)B substrate) 110 is prepared. Next, SiO₂ film 120 is deposited on the (111)B plane of the electroconductive GaAs substrate 110 by sputtering. A plurality of openings (through holes) are formed in the SiO₂ film 120 by photolithography and etching. The SiO₂ film 120 with the openings functions as a mask pattern. The shape of the opening is generally circular. The diameter of the opening is, for example, 80 nm. The openings are arrayed so that the center-to-center distance therebetween is, for example, 300 nm. Next, by MOCVD, the n-type GaAs nanorods 131 are grown from the (111)B plane of the electroconductive GaAs substrate 110 exposed through the openings. The substrate temperature in the MOCVD apparatus may be set, for example, to 750° C. Trimethylgallium gas may be used as a gallium raw material gas; arsenic hydride gas, as an arsenic raw material gas; and monosilane gas, as an n-type dopant.

Next, the first nondoped GaAs quantum barrier layer 133, the first nondoped InGaAs quantum well layer 134, the second nondoped GaAs quantum barrier layer 135, the second nondoped InGaAs quantum well layer 136 and the third nondoped GaAs quantum barrier layer 137 are grown around the n-type GaAs nanorods 131 by MOCVD. In the case of growing InGaAs, the substrate temperature in the MOCVD apparatus may be set, for example, to 680° C., and trimethylgallium gas may be used as a gallium raw material gas.

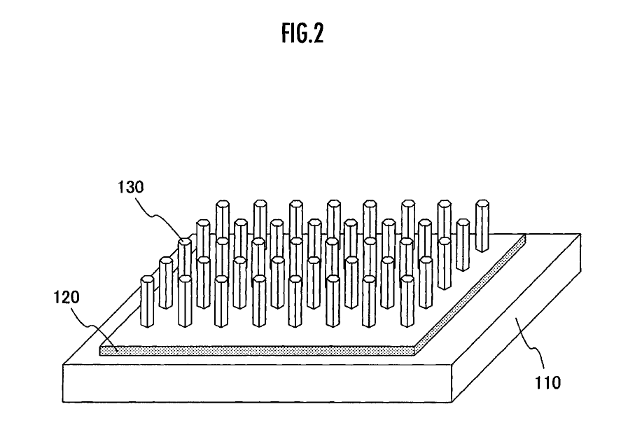

Next, the p-type GaAs layer 138 is grown around the third nondoped GaAs quantum barrier layer 137 by MOCVD. The substrate temperature in the MOCVD apparatus may be set, for example, to 680° C. In the n-type GaAs nanorods 131 and the p-type GaAs layer 138, a carrier density of, for example, 2×10¹⁸ to 5×10¹⁸ cm⁻³ may suffice. FIG. 2 is a perspective view showing the electroconductive GaAs substrate 110 after the growth of the semiconductor nanorods 130. FIG. 1 is a plan view showing the array of the semiconductor nanorods 130 in the electroconductive GaAs substrate 110 shown in FIG. 2. As shown in FIG. 1, the semiconductor nanorods 130 are each in the form of a hexagonal prism and are disposed in hexagonal close-packed array with a minimum diameter d and a pitch p.

Next, the semiconductor nanorods 130 on the electroconductive GaAs substrate 110 are embedded in the transparent embedment film 140 and the transparent embedment film 140 is thereafter reduced in thickness to expose head portions of the semiconductor nanorods 130. Subsequently, the transparent electrode 150 is formed on the transparent embedment film 140 and the second metal electrode 170 is formed on the transparent electrode 150. Also, the first metal 160 is formed on the surface of the electroconductive GaAs substrate 110 where the SiO₂ film 120 is not formed.

The solar cell element 100 in the present embodiment can be manufactured by the above-described procedure. The solar cell element 100 is used by being irradiated with light from the semiconductor nanorods 130 head side (transparent electrode 150 side).

While in the present embodiment the central portion of each semiconductor nanorod is n-type GaAs and the outermost portion of the semiconductor nanorod is p-type GaAs, the same advantage can also be obtained in a case where the central portion of each semiconductor nanorod is p-type GaAs and the outermost portion of the semiconductor nanorod is n-type GaAs.

### Third Embodiment

While in the second embodiment an example of the solar cell element of the present invention having quantum well layers is illustrated, an example of a solar cell element of the present invention further having a surface protective layer is illustrated in a third embodiment of the present invention.

The solar cell element in the third embodiment is identical in construction to the solar cell element 100 in the second embodiment shown in FIG. 4 except that the construction of the semiconductor nanorods is different. Description will therefore be made by reading a solar cell element 100′ in the third embodiment in place of the solar cell element 100 in the second element, and semiconductor nanorods 130′ in place of the semiconductor nanorods 130 in FIG. 4. The components identical to those of the solar cell element 100 in the second embodiment are indicated by the same reference numerals, and the description of the portions appearing again will not be repeated.

As shown in FIG. 4, the solar cell element 100′ in the third embodiment has an electroconductive GaAs substrate 110, a silicon oxide (SiO₂) film 120, semiconductor nanorods 130′, a transparent embedment film 140, a transparent electrode 150, a first metal electrode 160 and a second metal electrode 170.

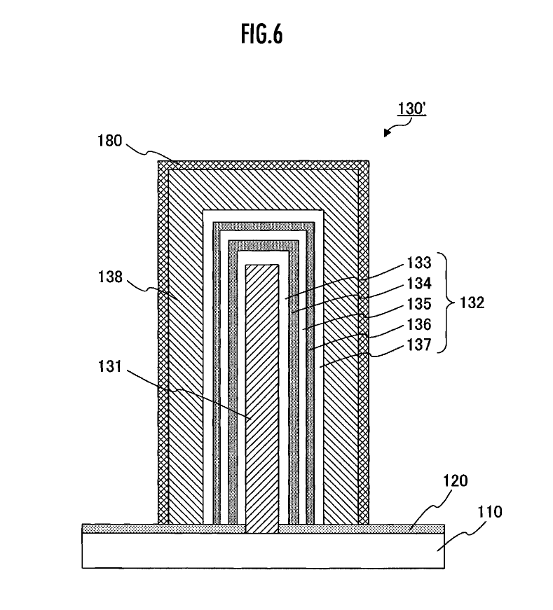

FIG. 6 is a sectional view of the semiconductor nanorod 130′ of the solar cell element 100′ in the third embodiment. As shown in FIG. 6, the semiconductor nanorod 130′ has an n-type GaAs nanorod 131 (central nanorod), a nondoped GaAs layer (first cover layer) 132 covering the n-type GaAs nanorod 131 and having quantum well layers, a p-type GaAs layer (second cover layer) 138 covering the nondoped GaAs layer 132, and a surface protective layer 180 covering the p-type GaAs layer 138.

The surface protective layer 180 is a protective film covering the p-type GaAs layer 138. The material of the surface protective layer 180 is not particularly specified if it is a material having an energy bandgap larger than that of p-type GaAs. Examples of such a material include GaP, InGaP, AlInP, AlGaAs, GaN, AlN, ZnO, ZnS, SiC and amorphous silicon (a-Si). In the case of forming the surface protective layer 180 by crystal growth, forming of the surface protective layer 180 may be performed by MOCVD, MBE or the like. In the case of forming the surface protective layer 180 formed of a-Si, forming of the surface protective layer 180 may be performed by CVD or the like.

Since the surface of each semiconductor nanorod 130′ is covered with a material of a large energy bandgap in the solar cell element 100′ in the third embodiment, the surface state for capturing carriers produced by application of light can be lowered. Thus, the solar cell element 100′ in the third embodiment is further improved in power generation efficiency in comparison with the solar cell element in the second embodiment.

### Fourth Embodiment

In a fourth embodiment of the present invention, an example of a solar cell element of the present invention having quantum dots is illustrated.

The solar cell element in the fourth embodiment is identical in construction to the solar cell element 100 in the second embodiment shown in FIG. 4 except that the constructions of the substrate and the semiconductor nanorods are different. Description will therefore be made by reading a solar cell element 200 in the fourth embodiment in place of the solar cell element 100 in the second element, an electroconductive InP substrate 210 in place of the electroconductive GaAs substrate 110 and semiconductor nanorods 220 in place of the semiconductor nanorods 130 in FIG. 4. The components identical to those of the solar cell element 100 in the second embodiment are indicated by the same reference numerals, and the description of the portions appearing again will not be repeated.

As shown in FIG. 4, the solar cell element 200 in the fourth embodiment has an electroconductive InP substrate 210, a silicon oxide (SiO₂) film 120, semiconductor nanorods 220, a transparent embedment film 140, a transparent electrode 150, a first metal electrode 160 and a second metal electrode 170.

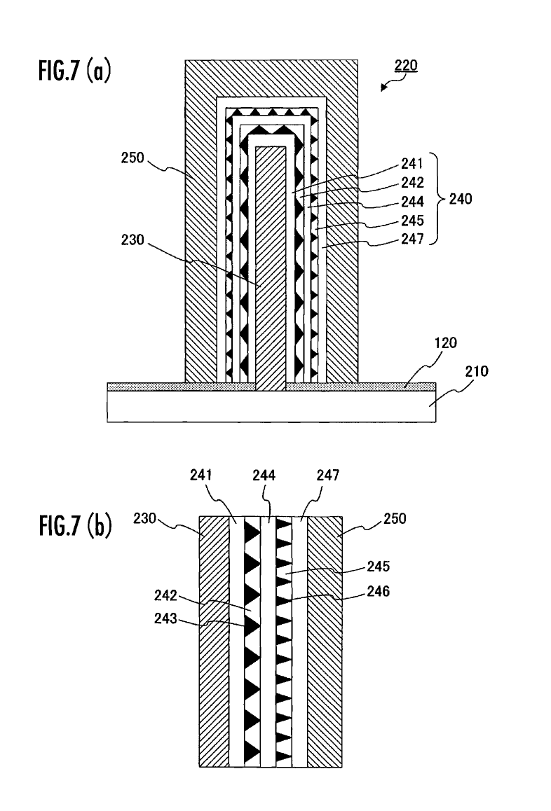

FIG. 7 is a sectional view of the semiconductor nanorod 220 of the solar cell element 200 in the fourth embodiment. FIG. 7(a) is a sectional view of the entire semiconductor nanorod, and FIG. 7(b) is an enlarged sectional view of a portion of the semiconductor nanorod.

As shown in FIGS. 7(a) and 7(b), the semiconductor nanorod 220 has an n-type InP nanorod (central nanorod) 230, a nondoped InP layer (first cover layer) 240 covering the n-type InP nanorod 230 and having a quantum dot structure, and a p-type InP layer (second cover layer) 250 covering the nondoped InP layer 240. The n-type InP nanorod 230 functions as an n-layer; the nondoped InP layer 240 functions as an i-layer; and the p-type InP layer 250 functions as a p-layer. That is, the n-type InP nanorod 230, the nondoped InP layer 240 and the p-type InP layer 250 form a p-i-n junction. The thickness of the n-type InP nanorod 230 at the foot end is, for example, 100 nm, and the height of the n-type InP nanorod 230 from the surface of the substrate 210 is, for example, 500 nm.

Also, as shown in FIGS. 7(a) and 7(b), the nondoped InP layer 240 has two nondoped InP buried layers. Each of these two nondoped InP buried layers is sandwiched between nondoped InP quantum barrier layers. That is, the nondoped InP layer 240 has a first nondoped InP quantum barrier layer 241 covering the n-type InP nanorod (central nanorod) 230; a first nondoped InP buried layer 242 covering the first nondoped InP quantum barrier layer 241; a second nondoped InP quantum barrier layer 244 covering the first nondoped InP buried layer 242; a second nondoped InP buried layer 245 covering the second nondoped InP quantum barrier layer 244; and a third nondoped InP quantum barrier layer 247 covering the second nondoped InP buried layer 245. The film thickness of the first nondoped InP buried layer 242 is, for example, 100 nm, and the film thickness of the second nondoped InP buried layer 245 is, for example, 50 nm. The film thickness of each of the nondoped InP quantum barrier layers 241, 244, and 247 is, for example, 50 nm.

Each of the two nondoped InP buried layers 242 and 245 contains solid crystals of InGaAs (or InAs) in land form. These crystals can function as a quantum well confining electrons and can therefore be regarded as InGaAs (or InAs) quantum dots. As shown in FIG. 7(b), the first nondoped InP buried layer 242 contains larger InGaAs quantum dots 243 and the second nondoped InP buried layer 245 contains smaller InGaAs quantum dots 246. By providing quantum dots in this way, the optical energy bandgap of the InGaAs quantum dots 246 contained in the second nondoped InP buried layer 245 can be increased relative to the optical energy bandgap of the InGaAs quantum dots 243 contained in the first nondoped InP buried layer 242. The energy bandgap of InP is larger than the energy bandgap of InGaAs quantum dots.

A method of manufacturing the solar cell element 200 in the fourth embodiment will be described with reference to the drawings.

First, the electroconductive InP substrate (InP(111)A substrate) 210 is prepared. Next, SiO₂ film 120 is deposited on the (111)A plane of the electroconductive InP substrate 210 by sputtering. A plurality of openings (through holes) are formed in the SiO₂ film 120 by photolithography and etching. The SiO₂ film 120 with the openings functions as a mask pattern. The shape of the opening is generally circular. The diameter of the opening is, for example, 100 nm. The openings are arrayed so that the center-to-center distance therebetween is, for example, 500 nm. Next, by MOCVD, the n-type InP nanorods 230 are grown from the (111)A plane of the electroconductive InP substrate 210 exposed through the openings. The substrate temperature in the MOCVD apparatus may be set, for example, to 650° C. Trimethylindium gas may be used as an indium raw material gas; tertiary butyl phosphine gas, as a phosphorus raw material gas; and monosilane gas, as an n-type dopant.

Next, a nondoped InP layer is grown as the first nondoped InP quantum barrier layer 241 around the n-type InP nanorod 230 by MOCVD. Preferably, at this time, the substrate temperature in the MOCVD apparatus is reduced, for example, to 600° C. to generally equalize the growth speed in the lengthwise direction of the n-type InP nanorod 230 and the growth speed in the radial direction of the n-type InP nanorod 230. After forming of the first nondoped InP quantum barrier layer 241, trimethylindium gas, trimethylgallium gas and tertiary butyl phosphine gas are simultaneously supplied and the supply is maintained for the same period of time as that for growing InGaAs film having a film thickness of several nm. At this time, an amount of In about 5 times or more larger than the amount of Ga is supplied as a III-group raw material, or only In is supplied. InGaAs (or InAs) thereby attached to the surface of the first nondoped InP quantum barrier layer 241 becomes solid crystals in land form (InGaAs quantum dots 243) due to the difference in crystal lattice constant between InP and InGaAs (or InAs) and surface tension of InGaAs (or InAs). Immediately after the completion of forming of the InGaAs quantum dots 243, the nondoped InP layer is again grown to enable the InGaAs quantum dots 243 to be buried in the first nondoped InP buried layer 242. This process is repeated to further grow the second nondoped InP quantum barrier layer 244, the second nondoped InP buried layer 245 (containing InGaAs quantum dots 246) and the third nondoped InP quantum barrier layer 247.

Next, the p-type InP layer 250 is grown around the third nondoped InP quantum barrier layer 247 by MOCVD. The substrate temperature in the MOCVD apparatus may be set, for example, to 600° C., and diethylzinc ((C₂H₅)₂Zn: DEZ) may be used as a p-type dopant. In the n-type InP nanorods 230 and the p-type InP layer 250, a carrier density of, for example, 1×10¹⁸ cm⁻³ may suffice.

Next, the semiconductor nanorods 220 on the electroconductive InP substrate 210 are embedded in the transparent embedment film 140 and the transparent embedment film 140 is thereafter reduced in thickness to expose head portions of the semiconductor nanorods 220. Subsequently, the transparent electrode 150 is formed on the transparent embedment film 140 and the second metal electrode 170 is formed on the transparent electrode 150. Also, the first metal electrode 160 is formed on the surface of the electroconductive InP substrate 210 where the SiO₂ film 120 is not formed.

The solar cell element 200 in the present embodiment can be manufactured by the above-described procedure. The solar cell element 200 is used by being irradiated with light from the semiconductor nanorods 220 head side (transparent electrode side).

The solar cell element 200 in the fourth embodiment has the same advantage as that of the solar cell element 100 in the second embodiment.

### Fifth Embodiment

While in the fourth embodiment an example of the solar cell element of the present invention having quantum dots is illustrated, an example of a solar cell element of the present invention further having a surface protective layer is illustrated in a fifth embodiment of the present invention.

The solar cell element in the fifth embodiment is identical in construction to the solar cell element 200 in the fourth embodiment except that the construction of the semiconductor nanorods is different. Description will therefore be made by reading a solar cell element 200′ in the fifth embodiment in place of the solar cell element 100 in the second element, an electroconductive InP substrate 210 in place of the electroconductive GaAs substrate 110, and semiconductor nanorods 220′ in place of the semiconductor nanorods 130 in FIG. 4. The components identical to those of the solar cell element 200 in the fourth embodiment are indicated by the same reference numerals, and the description of the portions appearing again will not be repeated.

As shown in FIG. 4, the solar cell element 200′ in the fifth embodiment has an electroconductive InP substrate 210, a silicon oxide (SiO₂) film 120, semiconductor nanorods 220′, a transparent embedment film 140, a transparent electrode 150, a first metal electrode 160 and a second metal electrode 170.

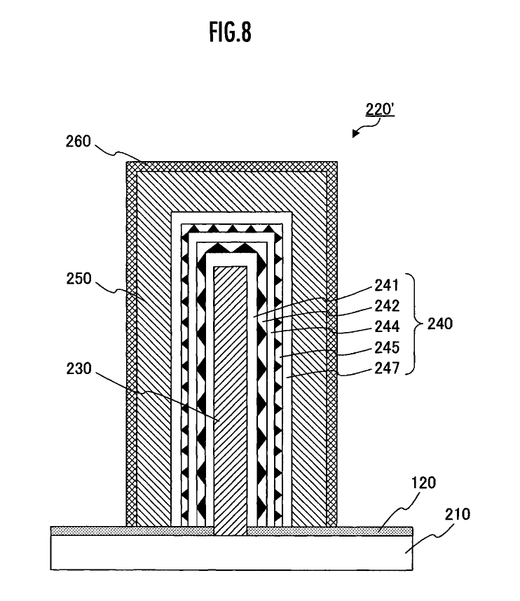

FIG. 8 is a sectional view of the semiconductor nanorod 220′ of the solar cell element 200′ in the fifth embodiment. As shown in FIG. 8, the semiconductor nanorod 220′ has an n-type InP nanorod 230 (central nanorod), a nondoped InP layer (first cover layer) 240 covering the n-type InP nanorod 230 and having quantum well layers, a p-type InP layer (second cover layer) 250 covering the nondoped InP layer 240, and a surface protective layer 260 covering the p-type InP layer 250.

The surface protective layer 260 is a protective film covering the p-type InP layer 240. The material of the surface protective layer 260 is not particularly specified if it is a material having an energy bandgap larger than that of p-type InP. Examples of such a material include InGaP, AlGaInP, GaP, InGaN, GaN, ZnS, SiC, SiO₂, SiN and Al₂O₃.

Since the surface of each semiconductor nanorod 220′ is covered with a material of a large energy bandgap in the solar cell element 200′ in the fifth embodiment, the surface state for capturing carriers produced by application of light can be lowered. Thus, the solar cell element 200′ in the fifth embodiment is further improved in power generation efficiency in comparison with the solar cell element in the third embodiment.

### Sixth Embodiment

In a sixth embodiment of the present invention, an example of a solar cell element of the present invention in which semiconductor nanorods have a tandem structure is illustrated.

The solar cell element in the sixth embodiment is identical in construction to the solar cell element 100 in the second embodiment shown in FIG. 4 except that the construction of the semiconductor nanorods is different. Description will therefore be made by reading a solar cell element 300 in the sixth embodiment in place of the solar cell element 100 in the second element, and semiconductor nanorods 310 in place of the semiconductor nanorods 130 in FIG. 4. The components identical to those of the solar cell element 100 in the second embodiment are indicated by the same reference numerals, and the description of the portions appearing again will not be repeated.

As shown in FIG. 4, the solar cell element 300 in the sixth embodiment has an electroconductive GaAs substrate 110, a silicon oxide (SiO₂) film 120, semiconductor nanorods 310, a transparent embedment film 140, a transparent electrode 150, a first metal electrode 160 and a second metal electrode 170.

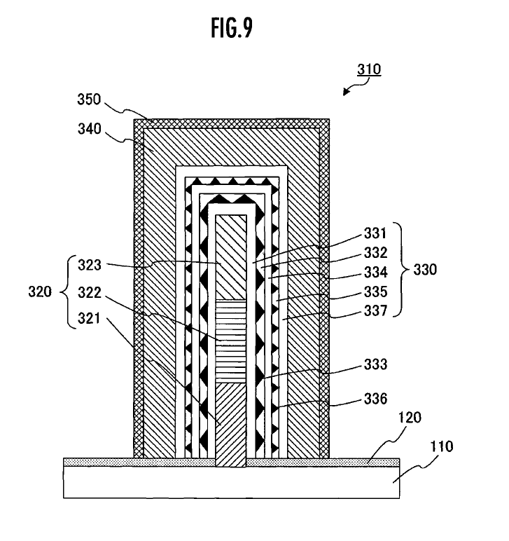

FIG. 9 is a sectional view of the semiconductor nanorod 310 of the solar cell element 300 in the sixth embodiment. As shown in FIG. 9, the semiconductor nanorod 310 has a central nanorod 320 formed of an n-type GaAs region 321, an n-type AlGaAs region 322 and an n-type GaN region 323, a nondoped GaN layer 330 covering the central nanorod 320 and having quantum dots, a p-type GaN layer 340 covering the nondoped GaN layer 330, and a surface protective layer 350 covering the p-type GaN layer 340. The central nanorod 320 functions as an n-layer; the nondoped GaN layer 330 functions as an i-layer; and the p-type GaN layer 340 functions as a p-layer. That is, the central nanorod 320, the nondoped GaN layer 330 and the p-type GaN layer 340 form a p-i-n junction. The diameter of the central nanorod 320 at the foot end is, for example, 80 nm, and the length of the central nanorod 320 from the surface of the electroconductive GaAs substrate 110 is, for example, 1500 nm. The length of each of the n-type GaAs region 321, the n-type AlGaAs region 322 and the n-type GaN region 323 is, for example, 500 nm. The n-type GaAs region 321 is positioned on the electroconductive GaAs substrate 110 side, while the n-type GaN region 323 is positioned on the transparent electrode 150 side. The n-type AlGaAs region 322 is positioned between the n-type GaAs region 321 and the n-type GaN region 323. That is, the semiconductors (n-type GaAs, n-type AlGaAs and n-type GaN) are arranged in order of decreasing energy bandgap from the transparent electrode 150 side.

As shown in FIG. 9, the nondoped GaN layer 330 has two nondoped GaN buried layers. Each of these two nondoped GaN buried layers is sandwiched between nondoped GaN quantum barrier layers. That is, the nondoped GaN layer 330 has a first nondoped GaN quantum barrier layer 331 covering the central nanorod 320; a first nondoped GaN buried layer 332 covering the first nondoped GaN quantum barrier layer 331; a second nondoped GaN quantum barrier layer 334 covering the first nondoped GaN buried layer 332; a second nondoped GaN buried layer 335 covering the second nondoped GaN quantum barrier layer 334; and a third nondoped GaN quantum barrier layer 337 covering the second nondoped GaN buried layer 335. The film thickness of the first nondoped GaN buried layer 332 is, for example, 100 nm, and the film thickness of the second nondoped GaN buried layer 335 is, for example, 50 nm. The film thickness of each of the nondoped GaN quantum barrier layers 331, 334, and 337 is, for example, 50 nm.

Each of the two nondoped GaN buried layers 332 and 335 contains solid crystals of InAs in land form. These crystals can function as a quantum well confining electrons and can therefore be regarded as InAs quantum dots. As shown in FIG. 9, the first nondoped GaN buried layer 332 contains larger InAs quantum dots 333 and the second nondoped GaN buried layer 335 contains smaller InAs quantum dots 336. By providing quantum dots in this way, the optical energy bandgap of the InAs quantum dots 336 contained in the second nondoped GaN buried layer 335 can be increased relative to the optical energy bandgap of the InAs quantum dots 333 contained in the first nondoped GaN buried layer 332. The energy bandgap of GaN is larger than the energy bandgap of InAs quantum dots.

A method of manufacturing the solar cell element 300 in the sixth embodiment will be described with reference to the drawings.

First, the electroconductive GaAs substrate (GaAs(111)B substrate) 110 is prepared. Next, SiO₂ film 120 is deposited on the (111)B plane of the electroconductive GaAs substrate 110 by sputtering. A plurality of openings (through holes) are formed in the SiO₂ film 120 by photolithography and etching. The SiO₂ film 120 with the openings functions as a mask pattern. The shape of the opening is generally circular. The diameter of the opening is, for example, 150 nm. The openings are arrayed so that the center-to-center distance therebetween is, for example, 500 nm. Next, by MOCVD, the n-type GaAs nanorod 321, the n-type AlGaAs nanorod 322 and the n-type GaN nanorod 323 are grown in this order from the (111)B plane of the electroconductive GaAs substrate 110 exposed through the openings. The substrate temperature in the MOCVD apparatus may be set, for example, to 800° C. Trimethylgallium gas may be used as a gallium raw material; trimethylaluminum gas, as an aluminum raw material gas; trimethylindium gas, as an indium raw material gas; arsenic hydride gas, as an arsenic raw material gas; ammonia gas, as a nitrogen raw material gas; and monosilane gas as an n-type dopant.

Next, a nondoped GaN layer is grown as the first nondoped GaN quantum barrier layer 331 around the central nanorod 320 by MOCVD. Preferably, at this time, the substrate temperature in the MOCVD apparatus is reduced, for example, to 700° C. to generally equalize the growth speed in the lengthwise direction of the central nanorod 320 and the growth speed in the radial direction of the central nanorod 320. After forming of the first nondoped GaN quantum barrier layer 331, trimethylindium gas and arsenic hydride gas are simultaneously supplied and the supply is maintained for the same period of time as that for growing InAs film having a film thickness of several nm. InAs thereby attached to the surface of the first nondoped GaN quantum barrier layer 331 becomes solid crystals in land form (InAs quantum dots 333) due to the difference in crystal lattice constant between GaN and InAs and surface tension of InAs. Immediately after the completion of forming of the InAs quantum dots 333, the nondoped GaN layer is again grown to enable the InAs quantum dots 333 to be buried in the first nondoped GaN buried layer 332. This process is repeated to further grow the second nondoped GaN quantum barrier layer 334, the second nondoped GaN buried layer 335 (containing InAs quantum dots 336) and the third nondoped GaN quantum barrier layer 337.

Next, the p-type GaN layer 340 is grown around the third nondoped GaN quantum barrier layer 337 by MOCVD. This process is repeated to further grow the AlGaN layer as the surface protective layer 350. The substrate temperature in the MOCVD apparatus may be set, for example, to 800° C., and an organic metal containing magnesium (Mg) or zinc (Z) may be used as a p-type dopant. In each of the central nanorod 320 and the p-type GaN layer 340, a carrier density of, for example, 1×10¹⁸ cm⁻³ may suffice.

Next, the semiconductor nanorods 310 on the electroconductive GaAs substrate 110 are embedded in the transparent embedment film 140 and the transparent embedment film 140 is thereafter reduced in thickness to expose head portions of the semiconductor nanorods 310. Subsequently, the transparent electrode 150 is formed on the transparent embedment film 140 and the second metal electrode 170 is formed on the transparent electrode 150. Also, the first metal 160 is formed on the surface of the electroconductive GaAs substrate 110 where the SiO₂ film 120 is not formed.

The solar cell element 300 in the present embodiment can be manufactured by the above-described procedure. The solar cell element 300 is used by being irradiated with light from the semiconductor nanorods 310 head side (transparent electrode side).

The solar cell element 300 in the sixth embodiment is capable of efficiently utilizing the solar light spectrum having energy lower than the energy bandgap (3.4 eV) of GaN while having the same advantage as that of the solar cell element in the first embodiment.

### Seventh Embodiment

In a seventh embodiment of the present invention, another example of the solar cell element of the present invention in which semiconductor nanorods have a tandem structure is illustrated.

The solar cell element in the seventh embodiment is identical in construction to the solar cell element 100 in the second embodiment shown in FIG. 4 except that the construction of the semiconductor nanorods is different. Description will therefore be made by reading a solar cell element 400 in the seventh embodiment in place of the solar cell element 100 in the second element, and semiconductor nanorods 410 in place of the semiconductor nanorods 130 in FIG. 4. The components identical to those of the solar cell element 100 in the second embodiment are indicated by the same reference numerals, and the description of the portions appearing again will not be repeated.

As shown in FIG. 4, the solar cell element 400 in the seventh embodiment has an electroconductive GaAs substrate 110, a silicon oxide (SiO₂) film 120, semiconductor nanorods 410, a transparent embedment film 140, a transparent electrode 150, a first metal electrode 160 and a second metal electrode 170.

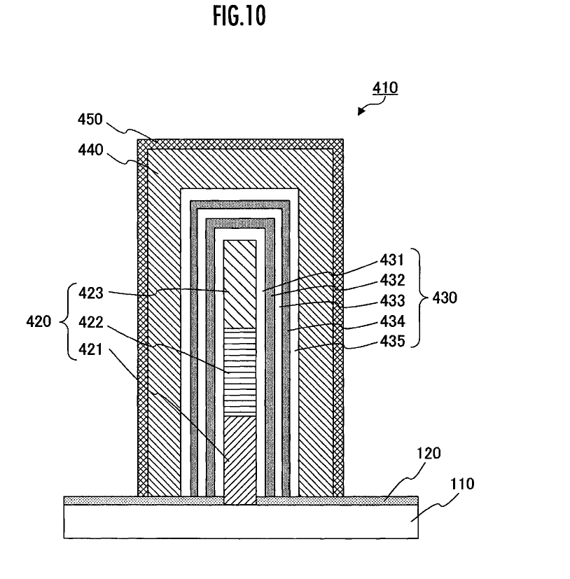

FIG. 10 is a sectional view of the semiconductor nanorod 410 of the solar cell element 400 in the seventh embodiment. As shown in FIG. 10, the semiconductor nanorod 410 has a central nanorod 420 formed of an n-type GaAs region 421, an n-type AlGaAs region 422 and an n-type GaInP region 423, a nondoped GaInP layer 430 covering the central nanorod 420 and having quantum well layers, a p-type GaInP layer 440 covering the nondoped GaInP layer 430, and a surface protective layer 450 covering the p-type GaInP layer 440. The central nanorod 420 functions as an n-layer; the nondoped GaInP layer 430 functions as an i-layer; and the p-type GaInP layer 440 functions as a p-layer. That is, the central nanorod 420, the nondoped GaInP layer 430 and the p-type GaInP layer 440 form a p-i-n junction. The diameter of the central nanorod 420 at the foot end is, for example, 80 nm, and the length of the central nanorod 420 from the surface of the electroconductive GaAs substrate 110 is, for example, 1500 nm. The length of each of the n-type GaAs region 421, the n-type AlGaAs region 422 and the n-type GaInP region 423 is, for example, 500 nm. The n-type GaAs region 421 is positioned on the electroconductive GaAs substrate 110 side, while the n-type GaInP region 423 is positioned on the transparent electrode 150 side. The n-type AlGaAs region 422 is positioned between the n-type GaAs region 421 and the n-type GaInP region 423. That is, the semiconductors (n-type GaAs, n-type AlGaAs and n-type GaInP) are arranged in order of decreasing energy bandgap from the transparent electrode 150 side.

As shown in FIG. 10, the nondoped GaInP layer 430 has two nondoped InGaAs quantum well layers. Each of these two nondoped InGaAs quantum well layers is sandwiched between nondoped GaInP quantum barrier layers. That is, the nondoped GaInP layer 430 has a first nondoped GaInP quantum barrier layer 431 covering the central nanorod 420; a first nondoped InGaAs quantum well layer 432 covering the first nondoped GaInP quantum barrier layer 431; a second nondoped GaInP quantum barrier layer 433 covering the first nondoped InGaAs quantum well layer 432; a second nondoped InGaAs quantum well layer 434 covering the second nondoped GaInP quantum barrier layer 433; and a third nondoped GaInP quantum barrier layer 435 covering the second nondoped InGaAs quantum well layer 434. The nondoped InGaAs quantum well layers 432 and 434 and the nondoped GaInP quantum barrier layers 431, 433, and 435 form a superlattice structure. Carriers can move freely in these nondoped InGaAs quantum well layers 432 and 434. The film thickness of the first nondoped InGaAs quantum well layer 432 is, for example, 10 nm, and the film thickness of the second nondoped InGaAs quantum well layer 434 is, for example, 5 nm. The film thickness of each of the nondoped GaInP quantum barrier layers 431, 433, and 435 is, for example, 30 nm.

The solar cell element 400 in the present embodiment can be manufactured by the same procedure as that for the solar cell elements in the second and sixth embodiments. The solar cell element 400 in the present embodiment is used by being irradiated with light from the semiconductor nanorods 410 head side (transparent electrode side).

The solar cell element 400 in the seventh embodiment has the same advantage as that of the solar cell element in the sixth embodiment.

### Eighth Embodiment

While in the embodiments 6 and 7 an example of the solar cell element of the present invention having semiconductor nanorods in a three-stage structure is illustrated, an example of the solar cell element of the present invention having semiconductor nanorods in a four-stage structure is illustrated in an eighth embodiment of the present invention.

The solar cell element in the eighth embodiment is identical in construction to the solar cell element 100 in the second embodiment shown in FIG. 4 except that the constructions of the substrate and the semiconductor nanorods are different. Description will therefore be made by reading a solar cell element 500 in the eighth embodiment in place of the solar cell element 100 in the second element, an electroconductive Si substrate 510 in place of the electroconductive GaAs substrate 110, and semiconductor nanorods 520 in place of the semiconductor nanorods 130 in FIG. 4. The components identical to those of the solar cell element 100 in the second embodiment are indicated by the same reference numerals, and the description of the portions appearing again will not be repeated.

As shown in FIG. 4, the solar cell element 500 in the eighth embodiment has an electroconductive Si substrate 510, a silicon oxide (SiO₂) film 120, semiconductor nanorods 520, a transparent embedment film 140, a transparent electrode 150, a first metal electrode 160 and a second metal electrode 170.

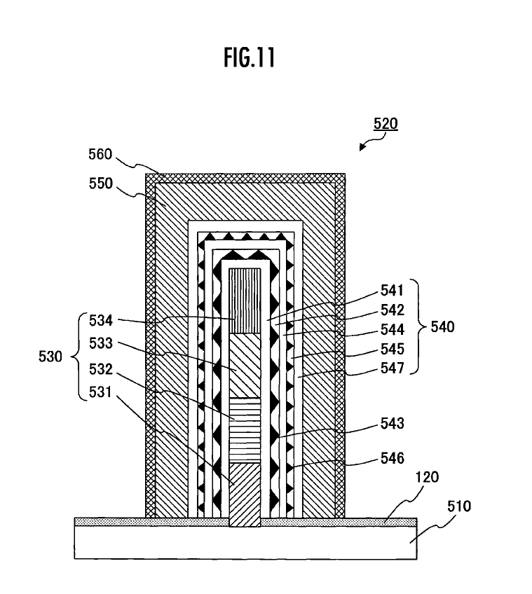

FIG. 11 is a sectional view of the semiconductor nanorod 520 of the solar cell element 500 in the eighth embodiment. As shown in FIG. 11, the semiconductor nanorod 520 has a central nanorod 530 formed of an n-type Ge region 531, an n-type GaAs region 532, an n-type GaAsP region 533 and an n-type GaInP region 534, a nondoped InGaN layer 540 covering the central nanorod 530 and having quantum dots, a p-type GaN layer 550 covering the nondoped InGaN layer 540, and a surface protective layer 560 covering the p-type GaN layer 550. The central nanorod 530 functions as an n-layer; the nondoped InGaN layer 540 functions as an i-layer; and the p-type GaN layer 550 functions as a p-layer. That is, the central nanorod 530, the nondoped InGaN layer 540 and the p-type GaN layer 550 form a p-i-n junction. The diameter of the central nanorod 530 at the foot end is, for example, 100 nm, and the length of the central nanorod 530 from the surface of the electroconductive Si substrate 510 is, for example, 1600 nm. The length of each of the n-type Ge region 531, the n-type GaAs region 532, the n-type GaAsP region 533 and the n-type GaInP region 534 is, for example, 400 nm. The semiconductors (n-type Ge, n-type GaAs, n-type GaAsP and n-type GaInP) are arranged in order of decreasing energy bandgap from the transparent electrode 150 side.

As shown in FIG. 11, the nondoped InGaN layer 540 has two nondoped InGaN buried layers. Each of these two nondoped InGaN buried layers is sandwiched between nondoped InGaN quantum barrier layers. That is, the nondoped InGaN layer 540 has a first nondoped InGaN quantum barrier layer 541 covering the central nanorod 530; a first nondoped InGaN buried layer 542 covering the first nondoped InGaN quantum barrier layer 541; a second nondoped InGaN quantum barrier layer 544 covering the first nondoped InGaN buried layer 542; a second nondoped InGaN buried layer 545 covering the second nondoped InGaN quantum barrier layer 544; and a third nondoped InGaN quantum barrier layer 547 covering the second nondoped InGaN buried layer 545. The film thickness of the first nondoped InGaN buried layer 542 is, for example, 50 nm, and the film thickness of the second nondoped InGaN buried layer 545 is, for example, 30 nm. The film thickness of each of the nondoped InGaN quantum barrier layers 541, 544, and 547 is, for example, 30 nm.

Each of the two nondoped InGaN buried layers 542 and 545 contains InAs quantum dots. As shown in FIG. 11, the first nondoped InGaN buried layer 542 contains larger InAs quantum dots 543 and the second nondoped InGaN buried layer 545 contains smaller InAs quantum dots 546. By providing quantum dots in this way, the optical energy bandgap of the InAs quantum dots 546 contained in the second nondoped InGaN buried layer 545 can be increased relative to the optical energy bandgap of the InAs quantum dots 543 contained in the first nondoped InGaN buried layer 542. The energy bandgap of InGaN is larger than the energy bandgap of InAs quantum dots.

The solar cell element 500 in the present embodiment is manufactured by generally the same procedure as that for the solar cell element in the sixth embodiment. The solar cell element 500 in the present embodiment is used by being irradiated with light from the semiconductor nanorods 520 head side (transparent electrode side).

The solar cell element 500 in the eighth embodiment can have the same advantage as that of the solar cell element in the sixth embodiment.

### Embodiment 9

In a ninth embodiment of the present invention, an example of a solar cell element in which each semiconductor nanorod has a plurality of heterojunctions is illustrated.

The solar cell element in the ninth embodiment is identical in construction to the solar cell element 100 in the second embodiment shown in FIG. 4 except that the construction of the semiconductor nanorods is different. Description will therefore be made by reading a solar cell element 600 in the ninth embodiment in place of the solar cell element 100 in the second element, and semiconductor nanorods 610 in place of the semiconductor nanorods 130 in FIG. 4. The components identical to those of the solar cell element 100 in the second embodiment are indicated by the same reference numerals, and the description of the portions appearing again will not be repeated.

As shown in FIG. 4, the solar cell element 600 in ninth embodiment has an electroconductive GaAs substrate 110, a silicon oxide (SiO₂) film 120, semiconductor nanorods 610, a transparent embedment film 140, a transparent electrode 150, a first metal electrode 160 and a second metal electrode 170.

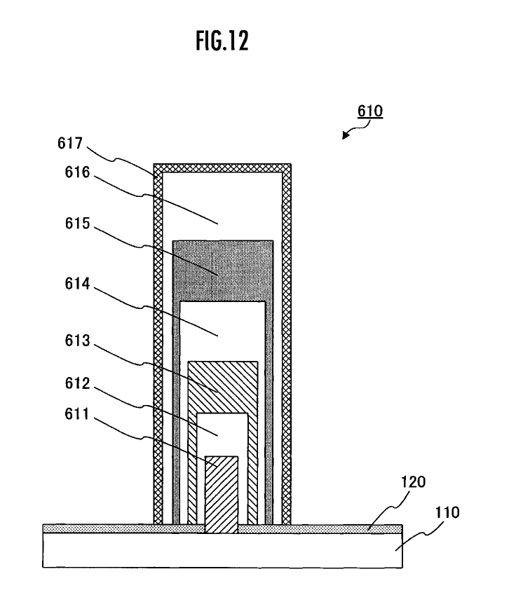

FIG. 12 is a sectional view of the semiconductor nanorod 610 of the solar cell element 600 in the ninth embodiment. As shown in FIG. 12, the semiconductor nanorod 610 has an n-type GaAs nanorod (central nanorod) 611, a p-type GaAs layer (first cover layer) 612 covering the n-type GaAs nanorod 611, an n-type AlGaAs layer (second cover layer) 613 covering the p-type GaAs layer 612, a p-type AlGaAs layer (third cover layer) 614 covering the n-type AlGaAs layer 613, an n-type GaInP layer (fourth cover layer) 615 covering the p-type AlGaAs layer 614, a p-type GaInP layer (fifth cover layer) 616 covering the n-type GaInP layer 615, and a surface protective layer 617 covering the p-type GaInP layer 616.

GaInP constituting the p-type GaInP layer (fifth cover layer) 616 and the n-type GaInP layer (fourth cover layer) 615 has an energy bandgap larger than that of AlGaAs constituting the p-type AlGaAs layer (third cover layer) 614 and the n-type AlGaAs layer (second cover layer) 613. Also, the energy bandgap of AlGaAs constituting the p-type AlGaAs layer (third cover layer) 614 and the n-type AlGaAs layer (second cover layer) 613 is larger than that of GaAs constituting the p-type GaAs layer (first cover layer) 612 and the n-type GaAs nanorod (central nanorod) 611. That is, in the semiconductor nanorod 610, the center nanorod and the semiconductor layers are formed so that n-type and p-type semiconductors are alternately positioned and the energy gap is successively increased from the center to an outer position.

Three p-n junctions are formed in the semiconductor nanorod 610. The first p-n junction is formed by the n-type GaAs nanorod (central nanorod) 611 and the p-type GaAs layer (first cover layer) 612. The second p-n junction is formed by the n-type AlGaAs layer (second cover layer) 613 and the p-type AlGaAs layer (third cover layer) 614. The third p-n junction is formed by the n-type GaInP layer (fourth cover layer) 615 and the p-type GaInP layer (fifth cover layer) 616. Thickness of the n-type GaAs nanorod 611 at the foot end is, for example, 50 nm. Also, the thickness of the semiconductor nanorod 610 is, for example, 400 nm and the height of the semiconductor nanorod 610 from the surface of the substrate 110 is, for example, 1800 nm.

The surface protective layer 617 is a protective film covering the p-type GaInP layer (fifth cover layer) 616. The material of the surface protective layer 617 is not particularly specified if it has an energy bandgap larger than that of the p-type GaInP layer.

A method of manufacturing the solar cell element 600 in the ninth embodiment will be described with reference to the drawings.

First, the electroconductive GaAs substrate (GaAs(111)B substrate) 110 is prepared. Next, SiO₂ film 120 is deposited on the (111)B plane of the electroconductive GaAs substrate 110 by sputtering. A plurality of openings (through holes) are formed in the SiO₂ film 120 by photolithography and etching. The SiO₂ film 120 with the openings functions as a mask pattern. The shape of the opening is generally circular. The diameter of the opening is, for example, 50 nm. The openings are arrayed so that the center-to-center distance therebetween is, for example, 300 nm. Next, by MOCVD, the n-type GaAs nanorods 611 having a diameter of 50 nm are grown from the (111)B plane of the electroconductive GaAs substrate 110 exposed through the openings. The substrate temperature in the MOCVD apparatus may be set, for example, to 750° C. Trimethylgallium gas may be used as a gallium raw material gas; arsenic hydride gas, as an arsenic raw material gas; and monosilane gas, as an n-type dopant.

Next, the p-type GaAs layer (first cover layer) 612 is grown around the n-type GaAs nanorods 611. At this time, it is preferable to set the speed of growth of the p-type GaAs layer 612 in the lengthwise direction higher than the speed of growth in the radial direction by reducing the substrate temperature in the MOCVD apparatus, for example, to 650 to 680° C. The substrate temperature in the MOCVD apparatus may be set, for example, to 680° C. Trimethylgallium gas may be used as a gallium raw material gas; arsenic hydride gas, as an arsenic raw material gas; and diethylzinc gas, as a p-type dopant.

Next, the n-type AlGaAs layer (second cover layer) 613 is grown around the p-type GaAs layer (first cover layer) 612. At this time, it is also preferable to set the speed of growth of the n-type AlGaAs layer 613 in the lengthwise direction higher than the speed of growth in the radial direction by setting the substrate temperature in the MOCVD apparatus, for example, to 750 to 850° C. The substrate temperature in the MOCVD apparatus may be set, for example, to 820° C. Trimethylaluminum gas may be used as an aluminum raw material gas; trimethylgallium, as a gallium raw material gas; arsenic hydride gas, as an arsenic raw material gas; and monosilane gas, as an n-type dopant.

Next, the p-type AlGaAs layer (third cover layer) 614 is grown around the n-type AlGaAs layer (second cover layer) 613. At this time, it is also preferable to set the speed of growth of p-type AlGaAs layer 614 in the lengthwise direction higher than the speed of growth in the radial direction by setting the substrate temperature in the MOCVD apparatus, for example, to 750 to 850° C. The substrate temperature in the MOCVD apparatus may be set, for example, to 820° C. Trimethylaluminum gas may be used as an aluminum raw material gas; trimethylgallium, as a gallium raw material gas; arsenic hydride gas, as an arsenic raw material gas; and diethylzinc gas, as a p-type dopant.

Next, the n-type GaInP layer (fourth cover layer) 615 is grown around the p-type AlGaAs layer (third cover layer) 614. At this time, it is also preferable to set the speed of growth of the n-type GaInP layer 615 in the lengthwise direction higher than the speed of growth in the radial direction by setting the substrate temperature in the MOCVD apparatus, for example, to 650 to 750° C. The substrate temperature in the MOCVD apparatus may be set, for example, to 700° C. Trimethylgallium gas may be used as a gallium raw material gas; trimethylindium gas, as an indium raw material gas; tertiary butyl phosphine gas, as a phosphorus raw material gas; and monosilane gas, as an n-type dopant.

Next, the p-type GaInP layer (fifth cover layer) 616 is grown around the n-type GaInP layer (fourth cover layer) 615. At this time, it is also preferable to set the speed of growth of the p-type GaInP layer 616 in the lengthwise direction higher than the speed of growth in the radial direction by setting the substrate temperature in the MOCVD apparatus, for example, to 650 to 750° C. The substrate temperature in the MOCVD apparatus may be set, for example, to 700° C. Trimethylgallium gas may be used as a gallium raw material gas; trimethylindium gas, as an indium raw material gas; tertiary butyl phosphine gas, as a phosphorus raw material gas; and diethylzinc gas, as a p-type dopant.

Next, the AlInP layer (surface protective layer) 617 is grown around the p-type GaInP layer (fifth cover layer) 616. At this time, it is preferable to equalize the speed of growth in the longitudinal direction and the speed of growth in the radial direction of the AlInP layer 617 by setting the substrate temperature in the MOCVD apparatus, for example, to 650 to 750° C. The substrate temperature in the MOCVD apparatus may be set, for example, to 700° C. Trimethylaluminum gas may be used as an aluminum raw material gas; trimethylindium gas, as an indium raw material gas; and tertiary butyl phosphine gas, as a phosphorus raw material gas. The thickness (diameter) and the height of the semiconductor nanorod 610 after the completion of forming of the surface protective layer 617 are about 400 nm and 1800 nm, respectively.

Next, the semiconductor nanorods 610 are embedded in the transparent embedment film 140 on the electroconductive GaAs substrate 110 and the transparent embedment film 140 is thereafter reduced in thickness to expose head portions of the semiconductor nanorods 610. Subsequently, the transparent electrode 150 is formed on the transparent embedment film 140 and the second metal electrode 170 is formed on the transparent electrode 150. Also, the first metal 160 is formed on the surface of the electroconductive GaAs substrate 110 where the SiO₂ film 120 is not formed.

The solar cell element 600 in the present embodiment can be manufactured by the above-described procedure. The solar cell element 600 is used by being irradiated with light from the semiconductor nanorods 610 head side (transparent electrode side).

The solar cell element 600 in the ninth embodiment can have the same advantage as that of the solar cell element 100 in the second embodiment.

### Tenth Embodiment

An a tenth embodiment of the present invention, an example of a color sensor of the present invention is illustrated.

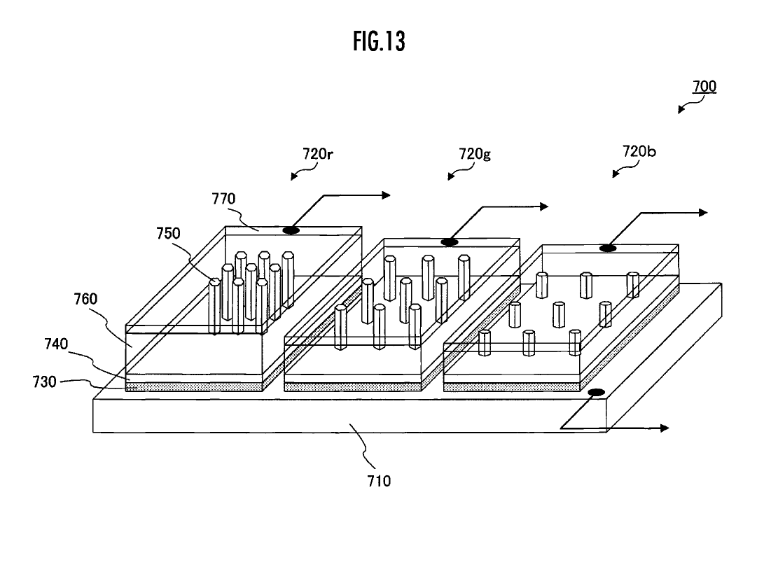

FIG. 13 is a perspective view showing the construction of a color sensor in the tenth embodiment. As shown in FIG. 13, a color sensor 700 in the tenth embodiment has an electroconductive substrate 710 and three rod arrays 720r, 720g, and 720b disposed on the electroconductive substrate 710. Each rod array 720 has a transparent electroconductive layer 730, an insulating film 740, semiconductor nanorods 750, a transparent embedment film 760 and a transparent electrode 770. The transparent electroconductive layer 730 and the insulating film 740 function as a mask pattern. Also, the electroconductive substrate 710 and transparent electrodes 770r, 770g, and 770b are connected to an external circuit, as shown in FIG. 13.

The electroconductive substrate 710 is an electroconductive n-type substrate.

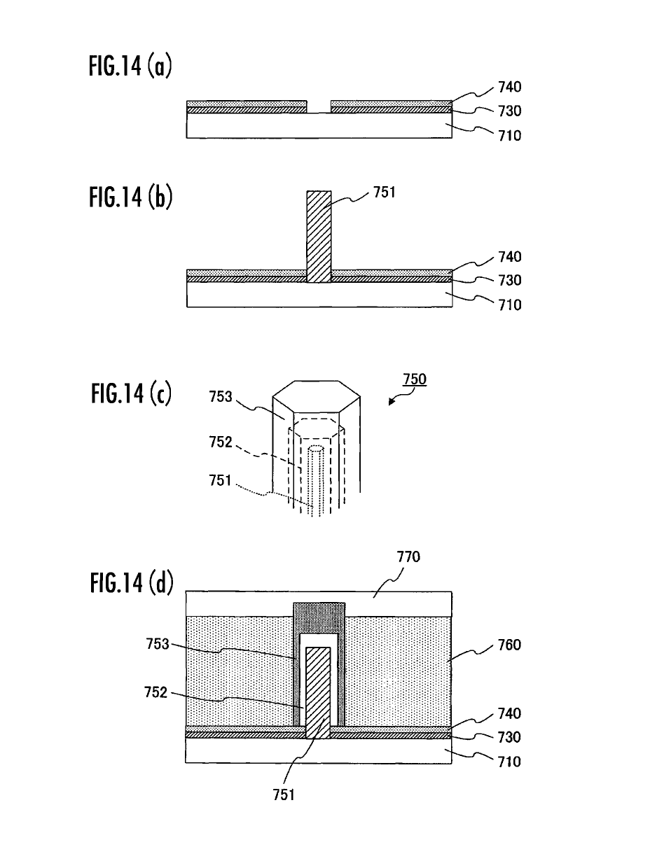

The transparent electroconductive layer 730 and the insulating film 740 cover the surface of the electroconductive substrate 710. In regions of the transparent electroconductive layer 730 and the insulating film 740 where the semiconductor nanorods 750 are disposed, openings are formed through the transparent electroconductive layer 730 and the insulating film 740. An n-type InGaN nanorod (central nanorod) 751 in each semiconductor nanorod 750 is in direct contact with the electroconductive substrate 710 (see FIG. 14), as described below.

A plurality of semiconductor nanorods 750 are disposed on the insulating film 740 so that their longitudinal axes are generally perpendicular to the surface of the electroconductive substrate 710. The outside diameter of the semiconductor nanorods 750 is, for example, 100 nm. In the first rod array 720r, the semiconductor nanorods 750r are arrayed so that the center-to-center distance is, for example, 500 nm. In the second rod array 720g, the semiconductor nanorods 750g are arrayed so that the center-to-center distance is, for example, 1500 nm. In the third rod array 720b, the semiconductor nanorods 750b are arrayed so that the center-to-center distance is, for example, 3000 nm.

Each semiconductor nanorod 750 has an n-type InGaN nanorod (central nanorod) 751, a nondoped InGaN layer (first cover layer) 752 covering the n-type InGaN nanorod 751, and a p-type InGaN layer (second cover layer) 753 covering the nondoped InGaN layer 752, as described below. The n-type InGaN nanorod 751 functions as an n-layer; the nondoped InGaN layer 752 functions as an i-layer; and the p-type InGaN layer 753 functions as a p-layer. That is, the n-type InGaN nanorod 751, the nondoped InGaN layer 752 and the p-type InGaN layer 753 form a p-i-n junction.

The n-type InGaN nanorod (central nanorod) 751 is in contact with the electroconductive substrate 710 and the transparent electroconductive layer 730, while each of the nondoped InGaN layer (first cover layer) 752 and the p-type InGaN layer (second cover layer) 753 is not in contact with the electroconductive substrate 710 and the transparent electroconductive layer 730.

The transparent embedment film 760 is an insulating film covering the side surfaces of the semiconductor nanorods 750 and filling the space between the semiconductor nanorods 750 in each of the rod arrays 720r, 720g, and 720b. Examples of the material of the transparent embedment film 760 include insulating resins, such as BCB resin and PIQ resin, and glass, such as PSG. Head portions of the semiconductor nanorods 750 (ends on the transparent electrode 770 side) are not covered with the transparent embedment film 760.

The transparent electrode 770 is disposed above the semiconductor nanorods 750 and is ohmic-connected to the p-type InGaN layers (second cover layers) 753 of the semiconductor nanorods 750.

A method of manufacturing the color sensor 700 in the tenth embodiment will be described with reference to FIG. 14. FIG. 14 is a schematic diagram showing a method of manufacturing the color sensor 700 in the present embodiment. For ease of description, a process of forming one semiconductor nanorod 750 is illustrated.

First, as shown in FIG. 14(a), the transparent electroconductive layer 730 and the insulating film 740 (mask pattern) are formed on the surface of the electroconductive substrate 710. A plurality of openings (through holes) are formed in the mask pattern by photolithography and etching. The diameter of the openings is within the range from 30 to 300 nm, and the center-to-center distance between the openings is within the range from 100 to 2000 nm. In each of the rod arrays 720r, 720g, and 720b, the openings are arranged in a 10×10 array.

Next, as shown in FIG. 14(b), the n-type InGaN nanorod (central nanorod) 751 is grown by a gas source MBE growth method from the surface of the electroconductive substrate 710 exposed through the opening. Trimethylgallium gas may be used as a gallium raw material gas; trimethylindium gas, as an indium raw material gas; ammonia gas, as a nitrogen raw material gas; and disilane (Si₂H₆) gas, as an n-type dopant.

In the gas source MBE growth process, the substrate temperature and the growth time are strictly controlled in order to control the diameter, length and composition of the n-type InGaN nanorods 751. The relationships between the diameter of the openings of the mask pattern, the center-to-center distance between the openings, the growth speed and the composition of the n-type InGaN nanorods 751 are as described below.
3) When the diameter of the openings is increased while the center-to-center distance between the openings of the mask pattern is fixed, the diameter of the n-type InGaN nanorods 751 is also increased. According to a study about the diameter and crystalline composition of the n-type InGaN nanorods 751, the In content increases substantially linearly from 10% to 70% when the diameter of the n-type InGaN nanorods 751 is increased from 50 nm to 450 nm. This tendency holds generally constant when the growth temperature is within the range from 600 to 700° C. When the temperature is further increased, the In content starts decreasing relative to Ga.
4) The center-to-center distance between the openings of the mask pattern is changed from 400 nm to 3000 nm while the diameter of the openings of the mask pattern is constantly maintained at the growth temperature 700° C. When the center-to-center distance between the grown n-type InGaN nanorods 751 is decreased, the In content increases from 20% to about 50%. When the temperature is increased to 800° C., the In content decreases to about half. In the relationship between the energy bandgap of InGaN and the In content x, an In content x of about 48% corresponds to the energy of blue light; an In content x of about 53% corresponds to the energy of green light; and an In content x of about 64% corresponds to the energy of red light.

Next, a shown in FIG. 14(c), the nondoped InGaN layer 752 and the p-type InGaN layer 753 are grown around the n-type InGaN nanorod 751 by the gas source MBE method. Trimethylgallium gas may be used as a gallium raw material gas; trimethylindium gas, as an indium raw material gas; ionized or activated nitrogen, as a nitrogen raw material gas; and an Mg solid source, as a p-type dopant.

Next, as shown in FIG. 14(d), lower halves of the semiconductor nanorods 750 are embedded in the transparent embedment film 760 in each of the rod arrays 720r, 720g, and 720b, and the transparent electrode 770 is thereafter formed on the transparent embedment film 760.

The color sensor 700 in the present embodiment can be manufactured by the above-described procedure. The color sensor 700 is used by being irradiated with light from the semiconductor nanorods 750 head side (transparent electrode 770 side). The rod array 720r has peak sensitivity most suitable for detection of red light; the rod array 720g has peak sensitivity most suitable for detection of green light; and the rod array 720b has peak sensitivity most suitable for detection of blue light.

The inventors of the present invention examined the photoreflectance of the color sensor 700 in the present embodiment to find that the color sensor 700 had a reduced photoreflectance which was ¼ of that of the conventional color sensor in the film structure. That is, the color sensor 700 in the present embodiment has an improved S/N ratio with respect to weak light in comparison with the conventional color sensor.

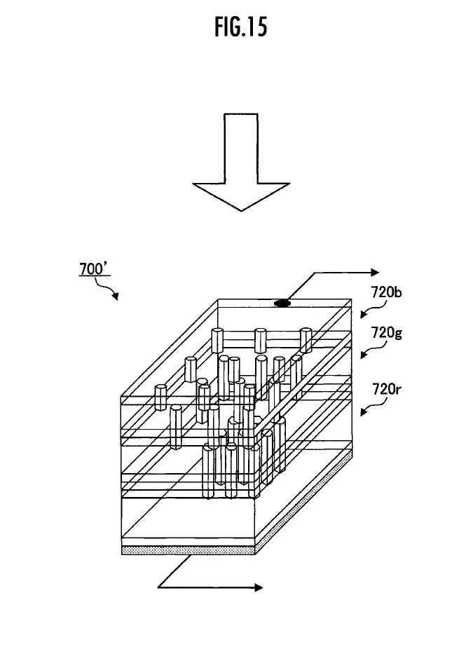

FIG. 15 is a perspective view of a state of three rod arrays 720r, 720g, and 720b cut out and stacked to form a color sensor 700′. In this case, in the substrate of the rod arrays 720g and 720b, a transparent substrate such as a quartz or sapphire substrate through which visible light can pass is used. In the color sensor 700′, blue light contained in incident light (indicated by a blank arrow in FIG. 15) is absorbed in the rod array 720b in the uppermost stage, and green light and red light pass therethrough toward the bottom side. Green light in the incident light that passed through the rod array 720b is absorbed in the rod array 720g in the middle stage. Red light passes through the rod array 720g to be absorbed in the rod array 720r in the bottom stage.

### Eleventh Embodiment

In an eleventh embodiment of the present invention, an example of simultaneous manufacture by one crystal grow process of a light emitting element having semiconductor nanorods and a light receiving element having semiconductor nanorods is illustrated.

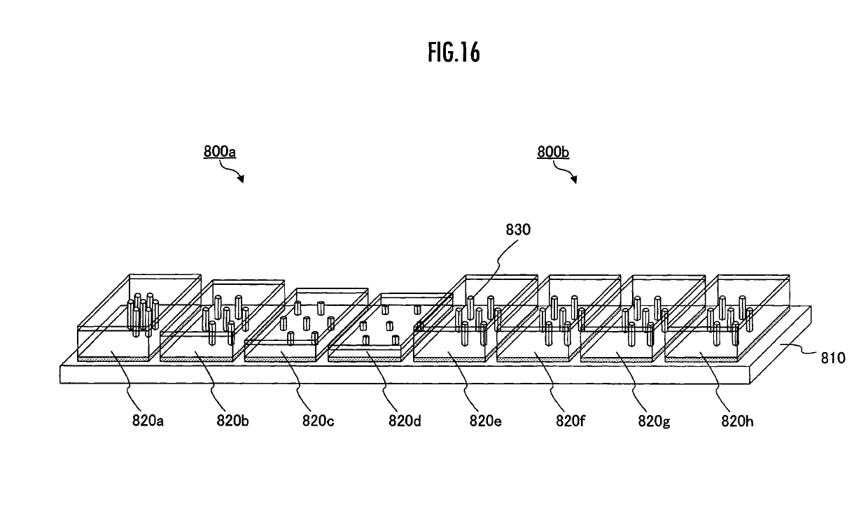

FIG. 16 is a perspective view of the construction of light emitting elements (LED array) 800a and light receiving elements (PD array) 800b simultaneously manufactured by a manufacturing method in the present embodiment.

As shown in FIG. 16, eight mask patterns 820a to 820h formed of insulating film (SiO₂ film) are formed on an N-type Si substrate 810. On the eight mask patterns 820a to 820h, four mask patterns 820a to 820d are for forming light emitting elements (LEDs), and four mask patterns 820e to 820h are for forming light receiving elements (PDs). Each mask pattern 820 has a 50×50 μm rectangular shape, and the center-to center distance between each adjacent pair of mask patterns 820 is 250 μm. In each of the mask patterns 820a to 820h, a plurality of openings are formed point-symmetrically or concentrically.

InGaAs nanorods 830 each containing a p-n junction or p-i-n junction are grown in the openings of the mask patterns by MOCVD. The relationship between the center-to-center distance between the openings of the mask pattern 820 and the In content in the InGaAs nanorods 830 was examined. The center-to-center distance and the In content were in such a relationship that when the center-to-center distance between the openings was increased from 500 nm in the mask pattern 820a to 3000 nm in the mask pattern 820d, the In content increased from 10% to 30% with respect to Ga. The relationship between the diameter of the openings of the mask patterns 820 and the In content in the InGaAs nanorods 830 was also examined. The diameter and the In content were in such a relationship that when the diameter of the openings was increased from 100 nm to 400 nm, the In content increased from 10% to 30%. In the mask patterns 820a to 820d shown in FIG. 16, the mask pattern 820a has a photoluminescence emission peak wavelength of 930 nm; the mask pattern 820b has a photoluminescence emission peak wavelength of 970 nm; the mask pattern 820c has a photoluminescence emission peak wavelength of 1010 nm; and the mask pattern 820d has a photoluminescence emission peak wavelength of 1060 nm. The diameter and the center-to-center distance of the openings in the mask patterns 820e to 820h were adjusted so that the photoluminescence peak wavelength was approximately 1050 nm.

The semiconductor nanorods 830 were embedded in transparent PSG, with their head portions exposed. Next, ohmic transparent electrodes and electrode patterns for lead-out to the outside were formed on the heads of the semiconductor nanorods 830, while a common ohmic electrode pattern was formed on the surface of the n-type Si substrate 810, thereby enabling performing an energization test. In an energized state, light from the LED sections having a peak at λ₁=940 nm on the shortest wavelength side was recognized, and emissions at three different wavelengths with wavelength intervals of 30 to 40 nm, longer than the shortest wavelength, were observed. It was also confirmed that photocurrents of several microamperes was obtained through the PD sections with respect to these four wavelengths.

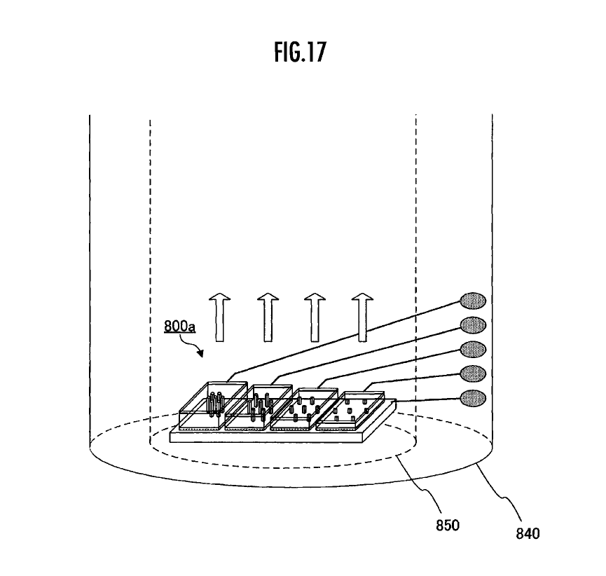

The LED array 800a and the PD array 800b can be parted into separate chips. The LED array 800a may be embedded in a multimode optical fiber as a light wave guide, as shown in FIG. 17. In such a case, the LED sections constituting the LED array are formed in a mask pattern having a diameter of 10 μm. In a semiconductor nanorod crystal growth process by MOCVD, the center-to-center distance between each adjacent pair of LED sections can be reduced to about 15 μm. Therefore the LED array 800a can be embedded by using a general-purpose multimode optical fiber in which the diameter of a core 850 is 60 μm. In the case of use as a communication light source, the LED array 800a can be used as a 4-wavelength light source for communication over about 10 km with only one optical fiber 840, without using an optical coupler. Advantageously, the optical fiber parts cost can be reduced to about ¼ in such a case.

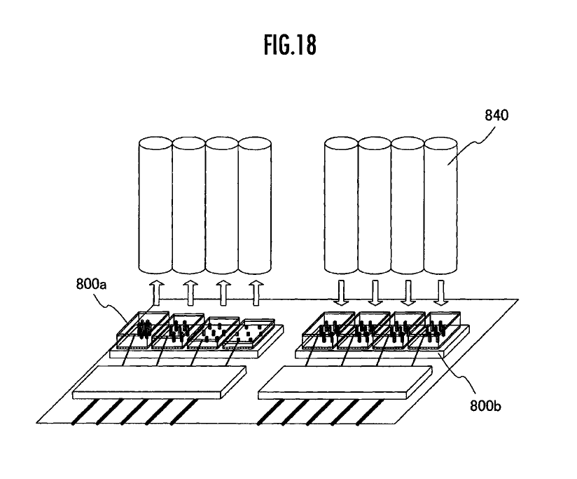

FIG. 18 is a perspective view of an example of implementation of a printed circuit board on which light emitting and receiving elements for short-distance communication over a communication distance of 1 km to about 10 km. A 4×1 LED array 800a is mounted in an optical output section, while a 4×1 PD array 800b is mounted in a light receiving section. The LED array and the PD array are respectively connected to optical fibers 840 for four channels. The LEDs in the optical output section have a communication speed of 2.5 gigabits/second (2.5 Gbps) per unit and the LEDs are capable of communication at a speed of 10 Gbps over the four channels combined.

What is claimed is:

1. A solar cell element comprising:
a substrate;
a mask pattern disposed on a surface of the substrate and having two or more openings;
two or more semiconductor nanorods extending upward from the surface of the substrate through the openings;
a first electrode connected to lower ends of the semiconductor nanorods; and
a second electrode connected to upper ends of the semiconductor nanorods,
wherein the semiconductor nanorods are disposed in triangular lattice form as viewed in plan on the substrate, and a ratio p/d of a center-to-center distance p between each adjacent pair of the semiconductor nanorods to a minimum diameter d of the semiconductor nanorods is within a range from 1 to 7, and
wherein each semiconductor nanorod has a central nanorod formed of a semiconductor of a first conduction type, a first cover layer formed of an intrinsic semiconductor and covering the central nanorod, and a second cover layer formed of a semiconductor of a second conduction type and covering the first cover layer.

2. The solar cell element according to claim 1, further comprising a surface protective layer covering the second cover layer and formed of a semiconductor having an energy bandgap larger than those of the semiconductor of the first conduction type, the semiconductor of the second conduction type and the intrinsic semiconductor.

3. The solar cell element according to claim 1 or 2, wherein the central nanorod has a first region formed of a first semiconductor and formed on the substrate, a second region formed of a second semiconductor having an energy bandgap larger than that of the first semiconductor and formed on the first region, and a third region formed of a third semiconductor having an energy bandgap larger than that of the second semiconductor and formed on the second region.

4. The solar cell element according to claim 3, wherein the central nanorod has a fourth region formed of a fourth semiconductor having an energy bandgap larger than that of the third semiconductor and formed on the third region.

5. The solar cell element according to any one of claims 1 to 4, wherein the first cover layer has a buried layer including a quantum well layer or quantum dots.

6. The solar cell element according to claim 5, wherein the first cover layer has two or more quantum barrier layers formed of a first intrinsic semiconductor, and a quantum well layer formed of a second intrinsic semiconductor having an energy bandgap smaller than that of the first intrinsic semiconductor, the quantum well layer being sandwiched between the quantum barrier layers.

7. The solar cell element according to claim 5, wherein the first cover layer has two or more quantum barrier layers formed of a first intrinsic semiconductor, and a buried layer including the first intrinsic semiconductor and quantum dots formed of a second intrinsic semiconductor having an energy bandgap smaller than that of the first intrinsic semiconductor, the buried layer being sandwiched between the quantum barrier layers, the quantum dots being dispersed in the first intrinsic semiconductor in the buried layer.

8. A solar cell element comprising:
a substrate;
a mask pattern disposed on a surface of the substrate and having two or more openings;
two or more semiconductor nanorods extending upward from the surface of the substrate through the openings;
a first electrode connected to lower ends of the semiconductor nanorods; and
a second electrode connected to upper ends of the semiconductor nanorods,
wherein each semiconductor nanorod has a central nanorod formed of a semiconductor of a first conduction type, a first cover layer formed of a semiconductor of a second conduction type and covering the central nanorod, a second cover layer formed of a semiconductor of the first conduction type and covering the first cover layer, a third cover layer formed of a semiconductor of the second conduction type and covering the second cover layer, a fourth cover layer formed of a semiconductor of the first conduction type and covering the third cover layer, and a fifth cover layer formed of a semiconductor of the second conduction type and covering the fourth cover layer,
wherein the semiconductors forming the fourth cover layer and the fifth cover layer have an energy bandgap larger than those of the semiconductors forming the second cover layer and the third cover layer, and
wherein the semiconductors forming the second cover layer and the third cover layer have an energy bandgap larger than that of the semiconductor forming the first cover layer.

9. A method of manufacturing a solar cell element, comprising:
forming a mask pattern having an opening on a surface of a substrate;
forming a central nanorod on the surface of the substrate exposed through the opening by causing crystal growth of a semiconductor of a first conduction type;
forming a first cover layer around the central nanorod by metal organic chemical vapor deposition, molecular beam epitaxy or chemical vapor deposition, the first cover layer being formed of an intrinsic semiconductor;
forming a second cover layer around the first cover layer, the second cover layer being formed of a semiconductor of a second conduction type; and
forming a first electrode and second electrode,
wherein the first cover layer has a quantum barrier layer formed by supplying a raw material gas of a first composition, and thereafter has a buried layer including a quantum well layer or quantum dots formed by supplying a raw material gas of a second composition.

10. A color sensor comprising:
a substrate;
a mask pattern disposed on a surface of the substrate, the mask pattern being sectioned into three or more regions corresponding to RGB, openings being formed in each of the three or more regions;
two or more semiconductor nanorods extending upward from the surface of the semiconductor substrate through the openings and having a p-n junction or a p-i-n junction;
a first electrode connected to lower ends of the semiconductor nanorods;
a second electrode connected to upper ends of the semiconductor nanorods,
wherein the composition of the semiconductor nanorods is changed with respect to the three or more regions.

11. A method of simultaneously manufacturing a light emitting element and a light receiving element, comprising:
A) preparing a substrate having a surface covered with a mask pattern,
the mask pattern being sectioned into a region where the light emitting element is to be formed and a region where the light receiving element is to be formed,
two or more openings through which a surface of the substrate is exposed being formed in each of the region where the light emitting element is to be formed and the region where the light receiving element is to be formed,
the size of the openings or the center-to-center distance between the openings being changed with respect to the region where the light emitting element is to be formed and the region where the light receiving element is to be formed; and
B) growing, through the openings, semiconductor nanorods from the substrate covered with the mask pattern, by forming a layer formed of an n-type semiconductor and forming a layer formed of a p-type semiconductor.
